(19) United States
(12) Patent Application Publication
(10) Pub. No.: US 2025/0248286 A1
(43) Pub. Date: Jul. 31, 2025

(54) DISPLAY DEVICE

(71) Applicant: LG Display Co., Ltd., Seoul (KR)

(72) Inventors: Yooji HWANG, Paju-si (KR); Yongmin KIM, Paju-si (KR)

(73) Assignee: LG Display Co., Ltd., Seoul (KR)

(21) Appl. No.: 18/958,249

(22) Filed: Nov. 25, 2024

(30) Foreign Application Priority Data
Jan. 29, 2024 (KR) 10-2024-0012990

(51) Int. Cl. H10K 59/80; H10K 59/38; H10K 59/40; H10K 102/00

(52) U.S. Cl. CPC H10K 59/879; H10K 59/38; H10K 59/40; H10K 2102/351

(57) ABSTRACT

A display device may have a structure where an area of a first depressed portion is greater than an area of a second depressed portion, and the number of lenses included in a first lens corresponding to the first depressed portion is greater than the number of lenses included in a second lens corresponding to the second depressed portion, and the display device is capable of improving light extraction efficiency.

### CROSS-REFERENCE TO RELATED APPLICATIONS

This application claims the benefit of and priority to Korea Patent Application No. 10-2024-0012990, filed on Jan. 29, 2024 in the Korean Intellectual Property Office, the entire contents of which are incorporated herein by reference for all purposes as if fully set forth herein.

### BACKGROUND

### 1. Technical Field

The present disclosure relates to electronic devices with displays, and particularly to, for example, without limitation, display devices.

### 2. Description of the Related Art

In today's information-oriented society, to meet various needs for display devices for displaying images, various types of displays, such as liquid crystal displays (LCD), organic light emitting displays (OLED), micro light emitting displays (micro LED), mini light emitting displays (mini LED), quantum dot light emitting displays (QLED), and the like have been developed and widely used.

Along with the development of information and communication technology, display devices have become increasingly important for serving to provide various information on a display screen.

To provide various information to users, display devices may be required to have excellent display quality and high luminous efficiency.

In particular, the luminous efficiency is becoming increasingly important because display devices are required to use limited power as multimedia technology advances.

The luminous efficiency of display devices may depend on the emission efficiency of light emitting elements included in the display devices.

Display devices including light emitting elements with high emission efficiency can have excellent luminous efficiency.

Therefore, to improve the luminous efficiency of display devices, it may be needed to improve the emission efficiency of light emitting elements.

However, there are several challenges to enhancing the emission efficiency of light emitting elements.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have developed a new invention. One or more aspects of the present disclosure are directed to an apparatus that substantially obviates one or more problems due to limitations and disadvantages of the related art.

One or more aspects of the present disclosure may provide a display device capable of improving light extraction efficiency.

One or more aspects of the present disclosure may provide a display device capable of being driven with low power based on a structure having high luminous characteristics.

According to one or more aspects of the present disclosure, a display device may be provided that is capable of improving light extraction efficiency.

According to one or more aspects of the present disclosure, a display device may be provided that is capable of being driven with low power based on a structure having high luminous characteristics.

According to one or more example embodiments of the present disclosure, a display device may include: a first light emitting area; a second light emitting area; a first depressed portion corresponding to the first light emitting area; a second depressed portion corresponding to the second light emitting area; a first lens corresponding to the first depressed portion; and a second lens corresponding to the second depressed portion. An area of the first depressed portion may be greater than an area of the second depressed portion, and an area of the first lens may be greater than an area of the second lens.

According to one or more example embodiments of the present disclosure, a display device may include: a first emission layer; and a second emission layer. In a first mode, the display device may be configured to emit light from the first emission layer and prevent emitting light from the second emission layer; and in a second mode, the display device may be configured to emit light from the second emission layer and prevent emitting light from the first emission layer. In the first mode, the light from the first emission layer may provide a first viewing angle in a first direction and a second viewing angle in a second direction; and in the second mode, the light from the second emission layer may provide one viewing angle in one direction and another viewing angle in another direction. The second emission layer may be different from the first emission layer; the second mode may be different from the first mode; the second direction may be different from the first direction; the another direction may be different from the one direction; and a range of the first viewing angle may be greater than a range of each of the second viewing angle, the one viewing angle, and the another viewing angle.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1A is a plan view of an example where a display device configured to allow switching between privacy protection modes operates in a narrow viewing angle mode according to aspects of the present disclosure;

FIG. 1B is a plan view of an example where the display device configured to allow switching between the privacy protection modes operates in a wide viewing angle mode according to aspects of the present disclosure;

FIG. 2 illustrates an example where the display device detects a touch based on a self-capacitive touch sensing configuration according to aspects of the present disclosure;

FIG. 3 is an example plan view illustrating subpixels disposed in an active area of the display device according to aspects of the present disclosure;

FIG. 4 is an example enlarged plan view for an area where a pixel group PG of FIG. 3 is disposed according to aspects of the present disclosure;

FIG. 5 is another example enlarged plan view for the area where the pixel group PG of FIG. 3 is disposed according to aspects of the present disclosure;

FIG. 6 is a plan view illustrating examples where the display device configured to allow switching between the privacy protection modes operates in each of the privacy protection modes according to aspects of the present disclosure;

FIG. 7A is an example perspective view of a first lens disposed in the display device according to one aspect of the present disclosure;

FIG. 7B is an example perspective view of a first lens disposed in the display device according to another aspect of the present disclosure;

FIG. 7C is an example perspective view illustrating a second lens disposed in the display device according to aspects of the present disclosure;

FIG. 8A is an example enlarged plan view of a first subpixel SP1 of FIG. 4 according to aspects of the present disclosure;

FIG. 8B is an example enlarged plan view of a second subpixel SP2 in FIGS. 4 and 5 according to aspects of the present disclosure;

FIG. 8C is an example enlarged plan view of a third subpixel SP3 of FIG. 5 according to aspects of the present disclosure;

FIG. 9A is an example cross-sectional view taken along line A-A′ of FIG. 4 according to one aspect of the present disclosure;

FIG. 9B is an example cross-sectional view taken along line A-A′ of FIG. 4 according to another aspect of the present disclosure;

FIG. 10 is an example cross-sectional view taken along with line B-B′ of FIG. 5 according to aspects of the present disclosure; and

FIG. 11 is an example cross-sectional view taken along line C-C′ of FIG. 5 according to aspects of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure. Further, the present disclosure is defined by the scope of claims and their equivalents.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, lenses, electrodes, filters, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, lenses, electrodes, filters, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, lenses, electrodes, filters, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, lens, electrode, filter, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” “third direction,” and the like (or the terms such as a first direction FD, a second direction SD, a third direction TD, and the like) should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, lens, electrode, filter, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

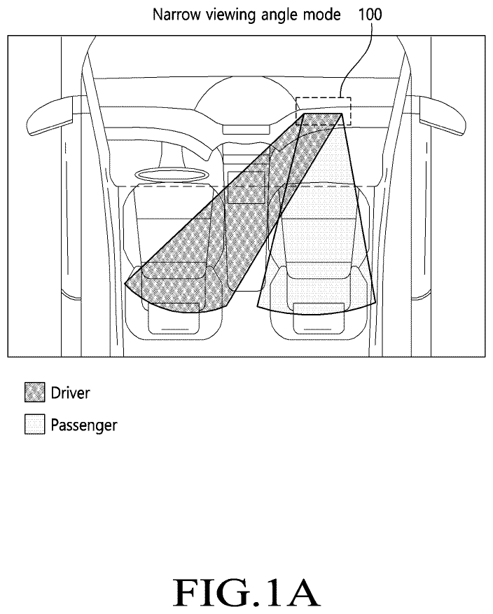

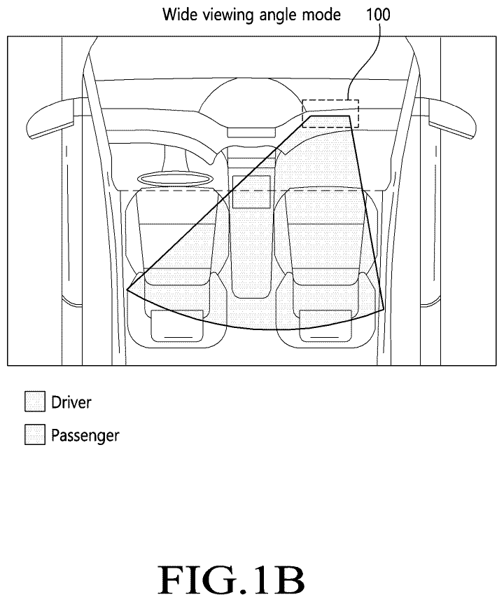

FIGS. 1A and 1B are plan views for examples where a display device 100 configured to allow switching between privacy protection modes is installed in front of a passenger seat of a vehicle such as an automobile, and operates in a narrow viewing angle mode and a wide viewing angle mode, respectively, which are the privacy protection modes.

As illustrated in FIG. 1A and FIG. 1B, the display device 100 capable of switching between the wide viewing angle mode and the narrow viewing angle mode may be installed in a portion of the vehicle located in front of the passenger seat.

However, locations in which the display device 100 is installed in the vehicle according to aspects of the present disclosure are not limited thereto. For example, the display device 100 capable of switching between the privacy protection modes may be installed in various locations such as a portion of the vehicle located in front of a driver seat, a back portion of the passenger seat, a back portion of the driver seat, and the like. Further, locations in which the display device 100 is disposed are not limited to vehicles, and the display device 100 may be disposed in any place where privacy protection is required or desired.

As illustrated in FIG. 1A, while operating in the narrow viewing angle mode, the display device 100 may present an image with the luminance of 1% or more to a passenger, but may present an image with the luminance of less than 1% to a driver.

For example, since only the passenger sitting in the passenger seat is provided with viewable brightness, and the driver sitting in the driver seat is not provided with viewable brightness, privacy protection can be provided only for the passenger sitting in the passenger seat.

As illustrated in FIG. 1B, while operating in the wide viewing angle mode, the display device 100 may present an image with the luminance of 1% or more to a passenger and a driver, and thereby, the image can be shared by both the passenger and the driver.

According to this configuration, in the wide viewing angle mode, the driver sitting in the driver seat, as well as the passenger sitting in the passenger seat, can be provided with viewable brightness.

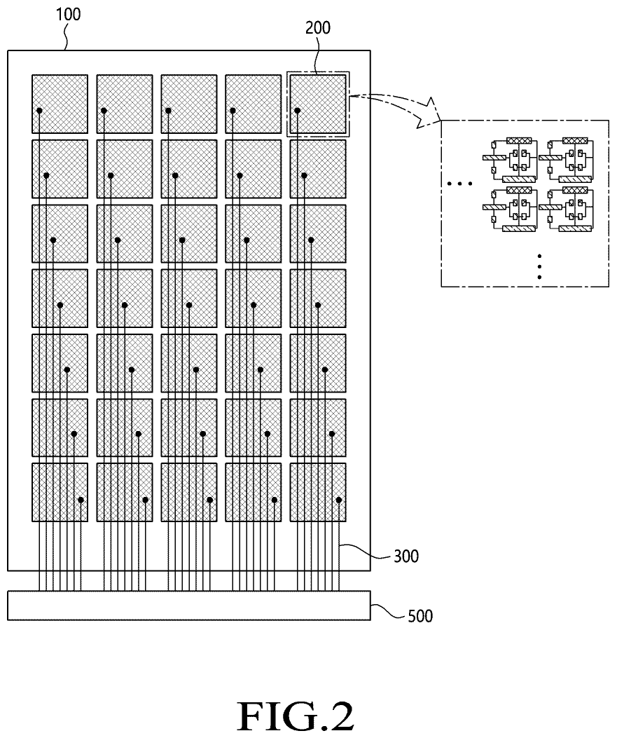

FIG. 2 illustrates an example where the display device 100 detects a touch based on a self-capacitive touch sensing configuration according to aspects of the present disclosure.

Referring to FIG. 2, in an example where the display device 100 detects a touch based on the self-capacitive touch sensing configuration, each of a plurality of touch sensors 200 disposed in the display device 100 can serve as both a driving touch electrode (to which a driving signal is applied) and a sensing touch electrode (from which a sensing signal is detected).

For example, a driving signal may be applied to each touch sensor 200, and a sensing signal may be received from each touch sensor 200 to which the driving signal is applied.

Therefore, in examples where the self-capacitive touch sensing configuration is applied, the touch sensors 200 are not divided into driving sensors (or electrodes) and sensing sensors (or electrodes).

When the self-capacitive touch sensing configuration is applied, a touch sensing circuit TSC can supply a driving signal to one or more touch sensors 200, receive sensing signals from the one or more touch sensors 200 to which the driving signal is applied, and based on the received sensing signals, detect whether a touch is applied and/or a location of the touch (or touch coordinates) based on a variance in capacitance between one or more touch sensors and an object such as a finger, a pen, or a conductive object.

Referring to FIG. 2, to deliver a driving signal and a sensing signal, each of a plurality touch sensors 200 may be electrically connected to a corresponding one of a plurality of conductive pads disposed in a pad 500 via a corresponding one of a plurality of touch lines 300.

The pad 500 including the conductive pads to which the touch lines 300 are connected may be connected to a touch sensing circuit (not shown).

The touch sensing circuit (not shown) can supply a touch driving signal to at least one of the plurality touch sensors 200, and detect whether a touch is applied and/or a location of the touch (or touch coordinates) in response to the touch driving signal.

Referring to FIG. 2, the plurality of touch sensors 200 may be disposed over a plurality of subpixels disposed in the display device or on a substrate.

It should be noted that the arrangement of the plurality of subpixels illustrated in FIG. 2 is one example, and aspects of the present disclosure are not necessarily limited thereto.

Referring to FIG. 2, a shape running along the edge of each of the plurality of touch sensors 200 may be, for example, a rhombus shape, or in some aspects, be a rectangle shape (which may include a square shape). However, aspects of the present disclosure are not limited thereto. For example, the touch sensors 200 may have various shapes.

Although FIG. 2 illustrates the example where the display device 100 has the self-capacitance touch sensing configuration, touch sensing configurations applied to the display device 100 according to aspects of the present disclosure are not limited thereto. For example, the display device 100 may have a mutual-capacitance touch sensing configuration.

In an example where the display device 100 has the mutual-capacitance touch sensing configuration, the display device 100 may include a plurality of connection patterns electrically connected to at least one of a plurality of touch sensors.

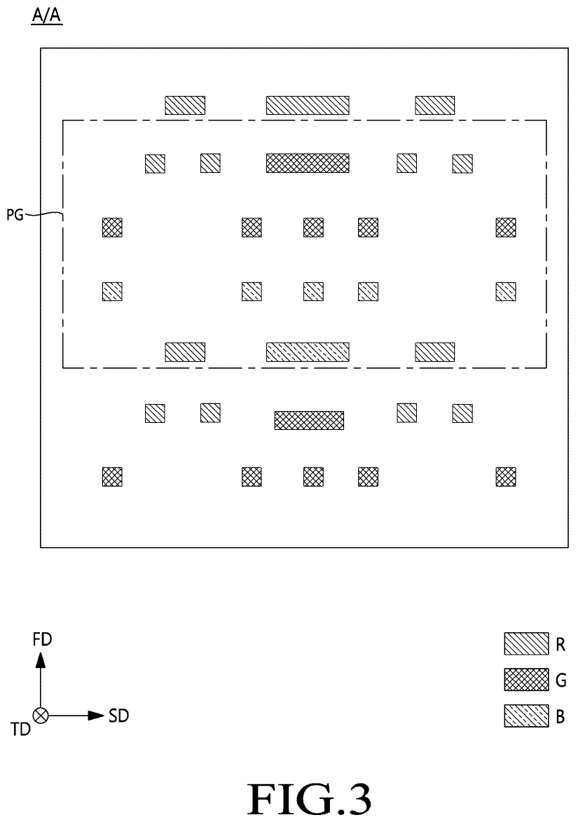

FIG. 3 is an example plan view illustrating subpixels disposed in an active area of the display device 100 according to aspects of the present disclosure.

Referring to FIG. 3, each of pixels disposed in an active area A/A of the display device 100 may include subpixels capable of emitting light of different colors for presenting color images.

The subpixels may include a red subpixel R, a green subpixel G, and a blue subpixel B.

The subpixels may further include a white subpixel, but for convenience of description, discussions on the configuration of FIG. 3 are provided based on an example where red subpixels R, green subpixels G, and blue subpixels B are included in pixels.

In one or more aspects, each red subpixel R, each green subpixel G, and each blue subpixel B may have different areas to implement switching between privacy protection modes.

For example, on a plane defined in a first direction FD and a second direction SD, a plurality of subpixels disposed in the display device and including a first subpixel and a second subpixel having an area smaller than the first subpixel may be disposed in the active area A/A of the display device 100.

In this configuration, a privacy protection system capable of switching between a wide viewing angle mode and a narrow viewing angle mode can be implemented by differently designing the size and arrangement of subpixels included in a pixel group PG among the subpixels disposed in the active area A/A of the display device 100 of FIG. 3.

However, the size and arrangement order of the subpixels disposed in the display device 100 to implement switching between the privacy protection modes are not limited thereto. In one or more aspects, discussions for the display device 100 capable of switching between the privacy protection modes are provided based on the arrangement of three first subpixels having a large area and fourteen second subpixels having a small area included in a pixel group PG in the configuration of FIG. 3.

Each of the subpixels included in the pixel group PG may include a pixel circuit and a light emitting element.

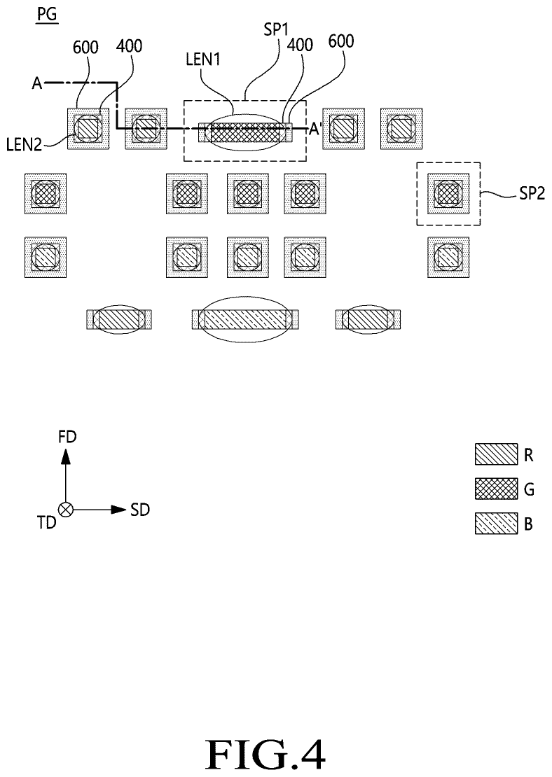

FIG. 4 is an enlarged plan view for an area where the pixel group PG of FIG. 3 is disposed according to aspects of the present disclosure.

Referring to FIG. 4, in one or more aspects, a plurality of depressed portions 400 may be disposed in a plurality of subpixels included in the pixel group PG.

In one or more aspects, when viewed in a plane defined in the first direction FD and the second direction SD, a plurality of planarization layers 600 (which may be also referred to as respective portions of a planarization layer 600) may be disposed adjacent to or surrounding the plurality of depressed portions 400.

Referring to FIG. 4, the pixel group PG may include a plurality of first subpixels SP1 and a plurality of second subpixels SP2.

Some of the subpixels (SP1 and SP2) may emit light of different colors.

For example, each first subpixel SP1 may include a red subpixel R capable of emitting red light, a green subpixel G capable of emitting green light, and/or a blue subpixel B capable of emitting blue light.

For example, each second subpixel SP2 may include a red subpixel R capable of emitting red light, a green subpixel G capable of emitting green light, and/or a blue subpixel B capable of emitting blue light.

It should be noted here that the arrangement of the subpixels (SP1 and SP2) and the arrangement of the red subpixels R, the green subpixels G, and the blue subpixels B as shown in the plan view of FIG. 4 is one example of applicable examples. Thus, aspects of the present disclosure are not necessarily limited to this, and various combinations may be applied in the display device 100.

Subpixels emitting light of different colors may include open areas with different areas or sizes.

For example, an area of the open area of each blue subpixel B emitting blue light may be the largest, and an area of the open area of each red subpixel R emitting red light may be the smallest.

This is because the characteristics of light emitting elements included in the subpixels emitting light of different colors may be different from each other.

However, aspects of the present disclosure are not necessarily limited thereto. For example, open areas of the subpixels may have the same area regardless of colors.

Referring to FIG. 4, a depressed portion disposed in any one of the first subpixels SP1 may surround a portion of an open area in the first subpixel, and a depressed portion disposed in any one of the second subpixels SP2 may surround an open area in the second subpixel.

Here, the surrounding of the open area of the second subpixel by the depressed portion may mean, for example, that the depressed portion completely surrounds an outer edge of the open area of the second subpixel when viewed in a plane defined in the first direction FD and the second direction SD.

Referring to FIG. 4, the planarization layers 600 (or portions of the planarization layer 600) may be disposed adjacent to one or more sides (or one or more side surfaces) of a plurality of lenses (LEN1, LEN2).

For example, the planarization layer 600 (or a portion of the planarization layer 600) in the first subpixel SP1 may be disposed adjacent to one or more sides (or one or more side surfaces) of a first lens LEN1 disposed in the first subpixel SP1, and the planarization layer 600 (or another portion of the planarization layer 600) in the second subpixel SP2 may surround a second lens LEN2.

Here, the surrounding of the second lens LEN2 by the planarization layer 600 (or the another portion of the planarization layer 600) may mean, for example, that the planarization layer 600 (or the another portion of the planarization layer 600) completely surrounds an outer edge of the second lens LEN2 when viewed in a plane defined in the first direction FD and the second direction SD.

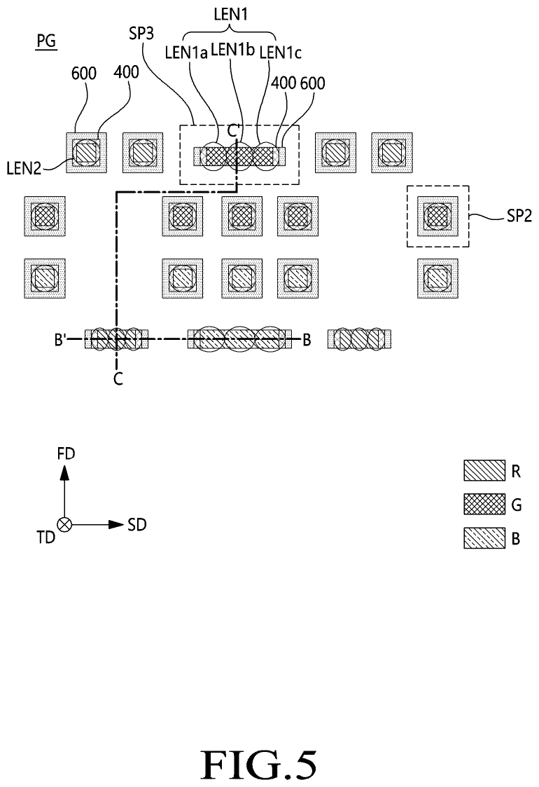

FIG. 5 is another example enlarged plan view for the area where the pixel group PG of FIG. 3 is disposed according to aspects of the present disclosure.

It should be noted that the configuration of red subpixels R, green subpixels G, and blue subpixels B of FIG. 5 may be substantially the same as the configuration of the red subpixels R, the green subpixels G, and the blue subpixels B described in FIG. 4.

It should be further noted that the configuration of depressed portions 400 and planarization layers 600 (or portions of a planarization layer 600) disposed in FIG. 5 may be substantially the same as the configuration of the depressed portions 400 and the planarization layers 600 (or the portions of the planarization layer 600) disposed in FIG. 4.

Referring to FIG. 5, one or more first lenses LEN1 and one or more second lenses LEN2 may include a plurality of lenses, respectively.

In this implementation, the number of lenses included in the first lens LEN1 and the number of lenses included in the second lens LEN2 may not be particularly limited. For example, it may be preferable that the number of lenses included in the first lens LEN1 is greater than the number of lenses included in the second lens LEN2.

In an example where the number of lenses included in the first lens LEN1 is greater than the number of lenses included in the second lens LEN2, the ratio of some light being randomly spread by the lenses among light extracted from a portion located under the lenses can increase, and thereby, in the wide viewing angle mode, the luminous efficiency and viewing angle of the display device 100 can be increased.

In one or more examples, unlike the first lens LEN1, it may be preferable that the second lens LEN2 has a smaller number of lenses, and more preferably, the number of lenses included in the second lens LEN2 may be 1.

In an example where the number of lenses included in the second lens LEN2 is 1, the ratio of some light being randomly spread by the lens among light extracted from a portion located under the lens can decrease, and thereby, the implementation of the display device 100 in the narrow viewing angle mode can be facilitated.

FIG. 5 illustrates that the number of lenses included in the first lens is 3, and the number of lenses included in the second lens is 1, but aspects of the present disclosure are not necessarily limited thereto.

In one or more aspects, the respective numbers of lenses included in first lenses or the respective numbers of lenses included in second lenses may be different from each other.

Referring to FIG. 5, the planarization layers 600 (or portions of the planarization layer 600) may be disposed adjacent to one or more sides (or one or more side surfaces) of a plurality of lenses (LEN1, LEN2).

For example, the planarization layer 600 (or a portion of the planarization layer 600) in a third subpixel SP3 may be disposed adjacent to one or more sides (or one or more side surfaces) of the first lens LEN1 disposed in the third subpixel SP3, and the planarization layer 600 (or another portion of the planarization layer 600) in a second subpixel SP2 may surround the second lens LEN2.

For example, among a first micro lens LEN1a, a second micro lens LEN1b, and a third micro lens LEN1c included in one first lens, the planarization layer 600 (or the portion of the planarization layer 600) may be disposed adjacent to respective sides (or side surfaces) of the first micro lens LEN1a and the third micro lens LEN1c.

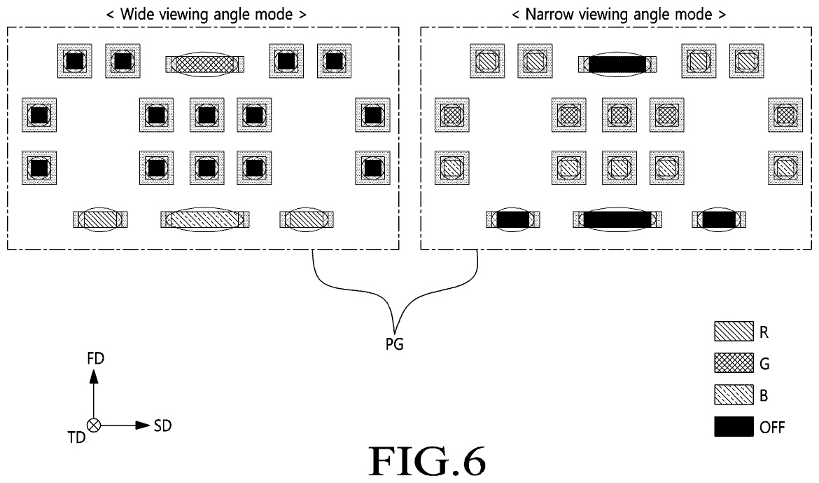

FIG. 6 is a plan view illustrating examples where the display device configured to allow switching between the privacy protection modes operates in each of the privacy protection modes according to aspects of the present disclosure.

FIG. 6 illustrates the example of the pixel group PG of FIG. 4.

Referring to FIG. 6, the display device 100 may operate in one of the wide viewing angle mode and the narrow viewing angle mode, which are switchable to each other, according to the convenience of a user (e.g., the passenger or driver of FIG. 1A and FIG. 1B).

In the wide viewing angle mode, to have a wide viewing angle, the display device 100 may be configured to allow a corresponding light emitting area of each first subpixel SP1 with a large area to emit light and not to allow a corresponding light emitting area of each second subpixel SP2 with an area smaller than the first subpixel SP1 to emit light (i.e., to be in an off state).

In the narrow viewing angle mode, to have a narrow viewing angle, the display device 100 may be configured to allow a corresponding light emitting area of each second subpixel SP2 with the area smaller than the first subpixel SP1 to emit light and not to allow a corresponding light emitting area of each first subpixel SP1 with the large area to emit light (i.e., to be in an off state).

In an example where the display device 100 is installed in a portion of a vehicle located in front of the passenger seat, in the wide viewing angle mode, a driver sitting in the driver seat, as well as a passenger sitting in the passenger seat, can be provided with viewable brightness.

In the narrow viewing angle mode, only the passenger sitting in the passenger seat can be provided with viewable brightness, and the driver sitting in the driver seat cannot be provided with viewable brightness. Thereby, privacy protection can be provided only for the passenger sitting in the passenger seat.

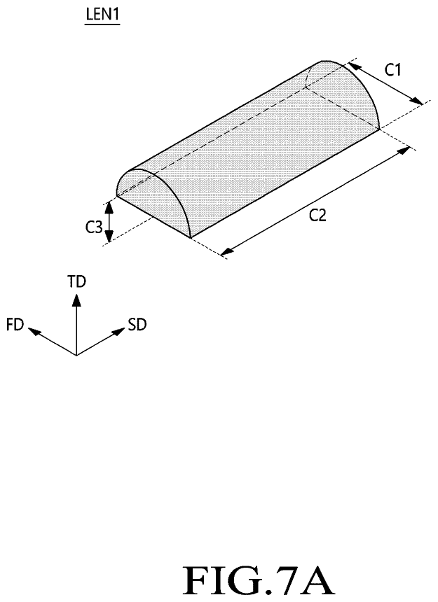

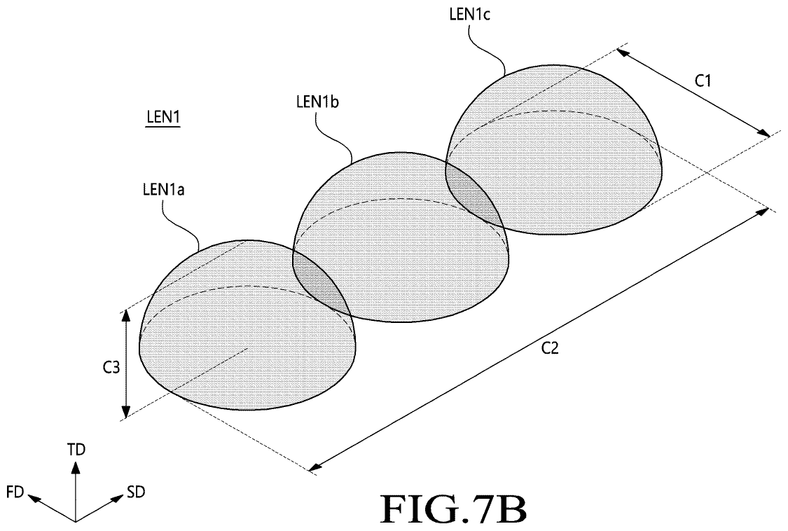

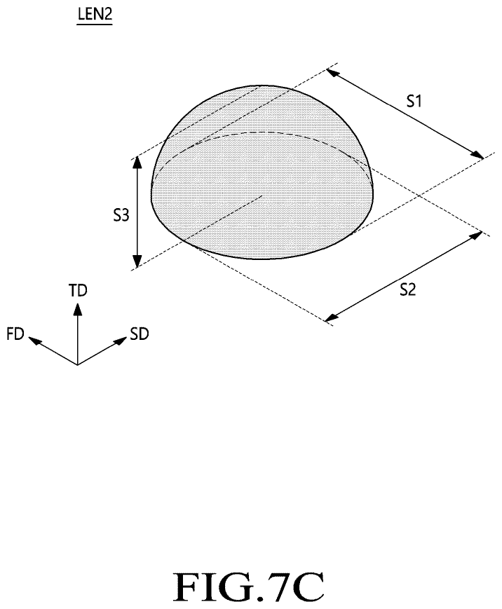

FIGS. 7A, 7B, and 7C are example perspective views of first lenses LEN1 and a second lens LEN2 disposed in the display device 100 according to aspects of the present disclosure.

FIG. 7A is an example perspective view of a first lens LEN1 disposed in the display device 100 according to one aspect of the present disclosure,

Referring to FIG. 7A, a first lens LEN1 corresponding to a first subpixel SP1 may have a semi-cylindrical shape having a diameter C1 in a first direction FD, a diameter C2 in a second direction SD, and a height C3 in a third direction TD.

The diameter C2 in the second direction SD of the first lens LEN1 may be greater than the diameter C1 in the first direction FD.

Although FIG. 7A illustrates that the first lens LEN1 has the semi-cylindrical shape, this may be one example of applicable examples, and aspects of the present disclosure are not limited thereto. For example, the first lens LEN1 may have various shapes depending on the shape of an open area of the first subpixel SP1.

For example, the height C3 in the third direction TD may be half of the diameter C1 in the first direction FD, but aspects of the present disclosure are not limited thereto. For example, the height C3 in the third direction TD may be greater or less than half of the diameter C1 in the first direction FD.

FIG. 7B is an example perspective view of a first lens LEN1 disposed in the display device 100 according to another aspect of the present disclosure.

Referring to FIG. 7B, a first lens LEN1 corresponding to a first subpixel SP1 may have a shape in which a plurality of lenses (LEN1a, LEN1b, LEN1c), each of which has a diameter C1 in a first direction FD, a diameter C2 in a second direction SD, and a height C3 in a third direction TD, are disposed.

The number of lenses included in the first lens LEN1 is not particularly limited. For the purpose of discussions, FIG. 7B illustrates an example in which the number of lenses included in the first lens LEN1 is three.

The first lens LEN1 may include a first micro lens LEN1a, a second micro lens LEN1b, and a third micro lens LEN1c.

The sum of respective diameters of the first micro lens LEN1a, the second micro lens LEN1b, and the third micro lens LEN1c may be equal to the diameter C2 of the first lens LEN1 in the second direction SD.

The respective diameters of the first micro lens LEN1a, the second micro lens LEN1b, and the third micro lens LEN1c are not particularly limited. Discussions on the configuration of FIG. 7B are provided based on an example in which the respective diameters of the first micro lens LEN1a, the second micro lens LEN1b, and the third micro lens LEN1c are C2/3.

Although FIG. 7B illustrates that the first lens LEN1 has a shape in which hemispheres are arranged side by side, this may be one example of applicable examples, and aspects of the present disclosure are not limited thereto. For example, the first lens LEN1 may have various shapes depending on the shape of an open area of the first subpixel SP1.

For example, the height C3 in the third direction TD may be half of the diameter C1 in the first direction FD, but aspects of the present disclosure are not limited thereto. For example, the height C3 in the third direction TD may be greater or less than half of the diameter C1 in the first direction FD.

FIG. 7C is an example perspective view illustrating a second lens LEN2 disposed in the display device 100 according to aspects of the present disclosure.

Referring to FIG. 7C, a second lens LEN2 corresponding to a second subpixel SP2 may have a hemispherical shape having a diameter S1 in a first direction FD, a diameter S2 in a second direction SD, and a height S3 in a third direction (TD).

The diameter S2 in the second direction SD and the diameter S1 in the first direction FD of the second lens LEN2 may be the same as each other.

Although FIG. 7C illustrates that the second lens LEN2 has the hemispherical shape, this may be one example of applicable examples, and aspects of the present disclosure are not limited thereto. For example, the second lens LEN2 may have various shapes depending on the shape of an open area of the second subpixel SP2.

For example, the height S3 in the third direction TD may be half of the diameter S1 in the first direction FD, but aspects of the present disclosure are not limited thereto. For example, the height C3 in the third direction TD may be greater or less than half of the diameter S1 in the first direction FD.

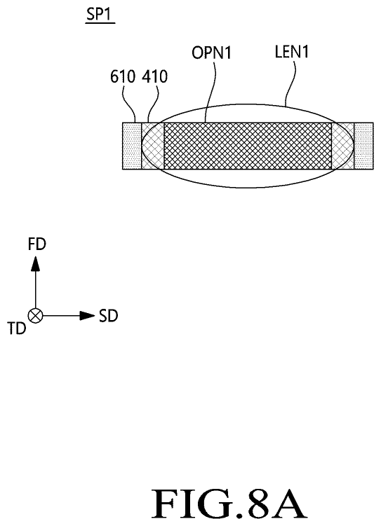

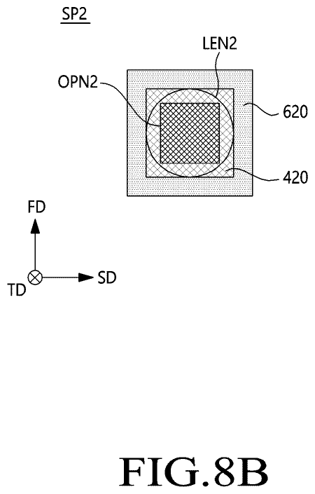

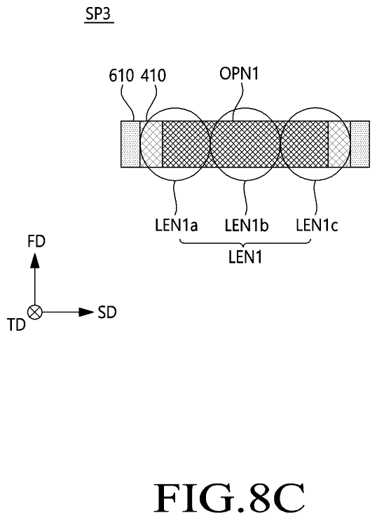

FIGS. 8A, 8B, and 8C are example enlarged plan views of the first subpixel SP1, the second subpixel SP2, and the third subpixel SP3 in FIGS. 4 and 5 according to aspects of the present disclosure.

Referring to FIG. 8A, the first subpixel SP1 may include a first open area OPN1 in the first subpixel, and a first depressed portion 410 surrounding the first open area OPN1.

For example, the first depressed portion 410 may be formed along short sides of the first open area OPN1.

However, aspects of the present disclosure are not necessarily limited thereto. For example, the first depressed portion 410 may be formed along long sides of the first open area OPN1, be formed by surrounding short sides and long sides of the first open area OPN1, or be formed in other various shapes. Discussions on the configuration of FIG. 8A are provided based on an example where the first depressed portion 410 is formed along short sides of the first open area OPN1.

The first depressed portion 410 may include a flat portion and an inclined portion surrounding the flat portion.

In this implementation, the first open area OPN1 may be surrounded by the inclined portion of the first depressed portion 410.

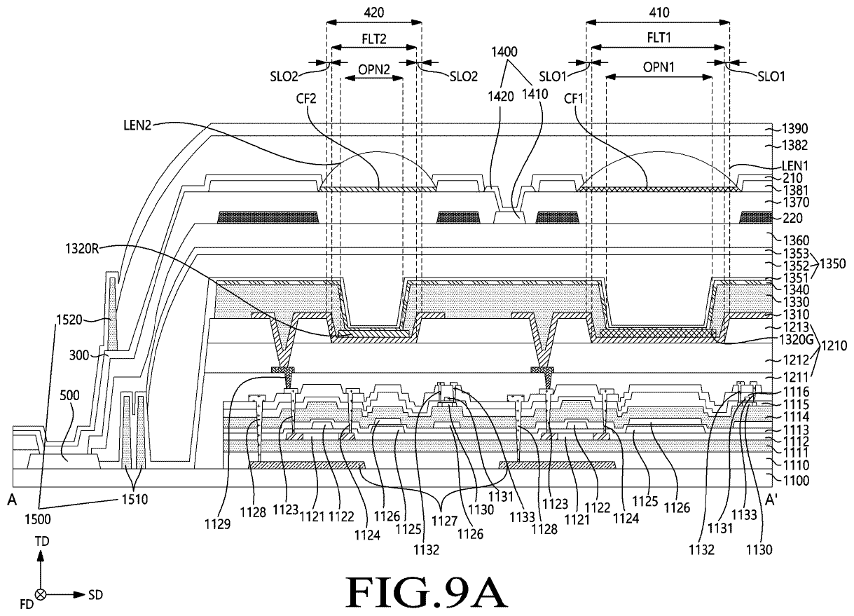

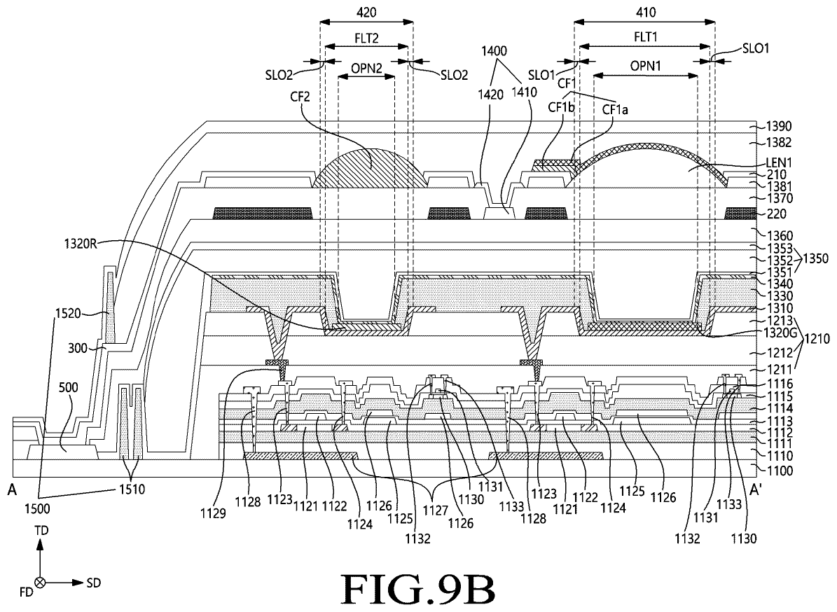

In one or more aspects, a light emitting area of the first subpixel SP1 may be depicted or represented by the first open area OPN1. In some examples, a light emitting area of the first subpixel SP1 may be depicted or represented by the first open area OPN1 and a first inclined portion SLO1 (see, e.g., FIG. 9A).

For example, the light emitting area of the first subpixel SP1 may be substantially the same or nearly the same as the first open area OPN1.

Herein, substantially the same or nearly the same may mean, for example, a degree of being considered as being equivalent to each other taking into account minute differences due to errors in the manufacturing process.

The first subpixel SP1 may include a first lens LEN1 corresponding to the first open area OPN1.

The first lens LEN1 of FIG. 8A may be substantially the same as the first lens LEN1 in FIG. 7A discussed above.

The first lens LEN1 may cover the first open area OPN1 in the first subpixel SP1 and the depressed portion disposed in the first subpixel SP1.

For example, the covering of the depressed portion disposed in the first subpixel SP1 by the first lens LEN1 may include, for example, that the first lens LEN1 covers all or a portion of the depressed portion disposed in the first subpixel SP1.

The first lens LEN1 can cause traveling paths of light emitted in the first open area OPN1 to be changed to improve emission efficiency. For example, the first lens LEN1 may be disposed to correspond to the first open area OPN1, and the shape of the first lens LEN1 may also correspond to the shape of the first open area OPN1. However, the shape of the first lens LEN1 according to aspects of the present disclosure is not necessarily limited to the shape of the first open area OPN1. For example, the first lens LEN1 may have various shapes depending on design requirements.

Referring to FIG. 8A, the depressed portion 410 disposed in the first subpixel SP1 may surround a portion of the first open area OPN1 in the first subpixel SP1.

In one or more aspects, referring to FIG. 8A, a first planarization layer 610 disposed in the first subpixel SP1 may be disposed adjacent to sides (or side surfaces) of the first lens LEN1.

For example, the first planarization layer 610 disposed in the first subpixel SP1 may surround respective portions of the side surfaces of the first lens LEN1.

When the first depressed portion 410 and the first planarization layer 610 are disposed as in the configuration of FIG. 8A, light from the first open area OPN1 in the first subpixel SP1 can be widely extracted in the second direction SD by the first depressed portion 410 and the first planarization layer 610, and at the same time, while a viewing angle in the first direction FD can be reduced by the first lens LEN1, a viewing angle in the second direction SD can be improved. Thereby, a wide viewing angle mode desired by a user can be implemented.

Referring to FIG. 8B, the second subpixel SP2 may include a second open area OPN2 in the second subpixel, and a second depressed portion 420 surrounding the second open area OPN2.

The second depressed portion 420 may include a flat portion and an inclined portion surrounding the flat portion.

In this implementation, the second open area OPN2 may be surrounded by the inclined portion of the second depressed portion 420.

In one or more aspects, a light emitting area of the second subpixel SP2 may be depicted or represented by the second open area OPN2. In some examples, a light emitting area of the second subpixel SP2 may be depicted or represented by the second open area OPN2 and a second inclined portion SLO2 (see, e.g., FIG. 9A).

For example, the light emitting area of the second subpixel SP2 may be substantially the same or nearly the same as the second open area OPN2.

The second subpixel SP2 may include a second lens LEN2 corresponding to the second open area OPN2.

The second lens LEN2 of FIG. 8B may be substantially the same as the second lens LEN2 in FIG. 7C discussed above.

The second lens LEN2 can cause traveling paths of light emitted in the second open area OPN2 to be changed to improve emission efficiency. For example, the second lens LEN2 may be disposed to correspond to the second open area OPN2, and the shape of the second lens LEN2 may also correspond to the shape of the second open area OPN2. However, the shape of the second lens LEN2 according to aspects of the present disclosure is not necessarily limited to the shape of the second open area OPN2. For example, the second lens LEN2 may have various shapes depending on design requirements.

Referring to FIG. 8B, the depressed portion 420 disposed in the second subpixel SP2 may surround the second open area OPN2 in the second subpixel SP2.

In one or more aspects, referring to FIG. 8B, a second planarization layer 620 disposed in the second subpixel SP2 may be disposed adjacent to sides (or side surfaces) of the second lens LEN2.

For example, the second planarization layer 620 disposed in the second subpixel SP2 may surround the side surfaces of the second lens LEN2.

When the second depressed portion 420 and the second planarization layer 620 are disposed as in the configuration of FIG. 8B, as the second open area OPN2 is surrounded by the inclined portion of the second depressed portion 420, the extraction of light from the second depressed portion 420 can be maximized, and while a viewing angle in the first direction FD can be reduced by the second lens LEN2, the light can be caused to be directed in a forward direction. Thereby, a narrow viewing angle mode desired by a user can be implemented.

Referring to FIG. 8C, a depressed portion 410 disposed in the third subpixel SP3 may surround a portion of a first open area OPN1 in the third subpixel SP3.

In one or more aspects, referring to FIG. 8C, a first planarization layer 610 disposed in the third subpixel SP3 may be disposed adjacent to sides (or side surfaces) of a first lens LEN1.

For example, the first planarization layer 610 disposed in the third subpixel SP3 may surround respective portions of the side surfaces of the first lens LEN1.

For example, among a first micro lens LEN1a, a second micro lens LEN1b, and a third micro lens LEN1c included in the first lens, the planarization layer 610 may be disposed adjacent to respective sides (or side surfaces) of the first micro lens LEN1a and the third micro lens LEN1c.

When the first depressed portion 410 and the first planarization layer 610 are disposed as in the configuration of FIG. 8C, light from the first open area OPN1 in the first subpixel SP1 can be widely extracted in the second direction SD by the first depressed portion 410 and the first planarization layer 610, and at the same time, while a viewing angle in the first direction FD can be reduced by the first lens LEN1, a viewing angle in the second direction SD can be improved. Thereby, a wide viewing angle mode desired by a user can be implemented.

In an example where the number of lenses included in the first lens LEN1 is great, the ratio of some light being randomly spread by the lenses among light extracted from a portion located under the lenses can increase, and thereby, in the wide viewing angle mode, the luminous efficiency and viewing angle of the display device 100 can be increased.

FIG. 9A is an example cross-sectional view taken along line A-A′ of FIG. 4 according to one aspect of the present disclosure.

The configuration of FIG. 9A may represent an area where a plurality of subpixel areas are disposed and a portion of a non-active area in the display device 100 according to aspects of the present disclosure.

Referring to FIG. 9A, in one or more aspects, the display device 100 may include a substrate 1100, an insulating layer 1210 disposed over the substrate 1100, a first electrode layer 1310 disposed on the insulating layer 1210, a bank layer 1330 disposed on the first electrode layer 1310 and the insulating layer 1210, an emission layer 1320 disposed on the first electrode layer 1310, a second electrode layer 1340 disposed on the emission layer 1320 (see, e.g., 1320G and 1320R) and the bank layer 1330, an encapsulation layer 1350 disposed on the second electrode layer 1340, a touch buffer layer 1360 disposed on the encapsulation layer 1350, a touch interlayer insulating layer 1370 disposed on the touch buffer layer 1360, and at least one planarization layer (1381, 1382) disposed on touch interlayer insulating layer 1370.

The display device 100 may include a first transistor disposed over the substrate 1100 and a light emitting element such as an organic light emitting element, an organic light emitting diode, and the like electrically connected to the first transistor in the active area.

The first transistor may include a first active layer 1121, a first gate electrode layer 1122, a first source electrode layer 1123, and a first drain electrode layer 1124.

The light emitting element may include the first electrode 1310, the emission layer 1320, and the second electrode 1340.

In one or more aspects, the first electrode 1310 may be an anode electrode layer, and the second electrode 1340 may be a cathode electrode layer, but aspects of the present disclosure are not limited thereto.

A first metal pattern 1127 may be disposed on the substrate 1100.

A first buffer layer 1110 may be disposed on the substrate 1100 and the first metal pattern 1127, and a second buffer layer 1111 may be disposed on the first buffer layer 1110.

The first active layer 1121 of the first transistor may be disposed on the second buffer layer 1111.

A first gate insulating layer 1112 may be disposed on the first active layer 1121, and the first gate electrode layer 1122 may be disposed on the first gate insulating layer 1112.

A first interlayer insulating layer 1113 may be disposed on the first gate electrode layer 1122, a third buffer layer 1114 may be disposed on the first interlayer insulating layer 1113, a second gate insulating layers 1115 may be disposed on the third buffer layer 1114, and a second interlayer insulating layer 1116 may be disposed on the second gate insulating layer 1115.

A second metal pattern 1128, the first source electrode layer 1123, and the first drain electrode layer 1124 may be disposed on the second interlayer insulating layer 1116.

The first source electrode layer 1123 and the first drain electrode layer 1124 may be configured to be spaced apart from each other on the second interlayer insulating layer 1116.

The first source electrode layer 1123 and the first drain electrode layer 1124 may contact respective portions of the first active layer 1121 through holes in the first gate insulating layer 1112, the first interlayer insulating layer 1113, the third buffer layer 1114, the second gate insulating layer 1115, and the second interlayer insulating layer 1116.

As described above, the first transistor may be disposed over the substrate 1100, but the configuration of the first transistor according to aspects of the present disclosure is not limited thereto.

In one or more aspects, the first active layer 1121 may be disposed over the substrate 1100, the first gate electrode layer 1122 may be disposed on the first active layer 1121, the first source electrode layer 1123 may be disposed on the first active layer 1121 and configured to overlap with a first portion of the first active layer 1121, and the first drain electrode layer 1124 may be configured to overlap with a second opposing portion of the first active layer 1121.

The insulating layer 1210 may be configured to cover the first transistor.

The insulating layer 1210 may include an organic material, but aspects of the present disclosure are not limited thereto.

The insulating layer 1210 may include a first insulating layer 1211, a second insulating layer 1212, and a third insulating layer 1213.

For example, the first insulating layer 1211 may be configured to cover the first transistor, the second insulating layer 1212 may be disposed on the first insulating layer 1211, and the third insulating layer 1213 may be disposed on the second insulating layer 1212.

However, aspects of the present disclosure are not necessarily limited thereto. The first insulating layer 1211 may be a single layer, or include four or more insulating layers.

The insulating layer 1210 may be disposed in a plurality of subpixels and may include a plurality of depressed portions 400 each located in a corresponding one of the plurality of subpixels. Herein, the term “depressed portion” may be also referred to as an opened portion.

Discussions on the configuration of FIG. 9A are provided based on an example where the insulating layer 1210 is disposed in a red subpixel R and a green subpixel G and includes a second depressed portion 420 and a first depressed portion 410 located in the red subpixel and the green subpixel, respectively.

The insulating layer 1210 may include a peripheral portion surrounding the depressed portions 400 and being located around the depressed portions 400.

Each depressed portion 400 may include a flat portion FLT and an inclined portion SLO surrounding the flat portion FLT.

For example, the second insulating layer 1212 may include the flat portion FLT, and the third insulating layer 1213 may include the inclined portion SLO.

However, aspects of the present disclosure are not limited thereto. For example, one of the insulating layers included in the insulating layer 1210 may include both the flat portion FLT and the inclined portion SLO of the depressed portion 400.

The flat portion FLT of the depressed portion 400 may be a portion whose surface is parallel to a surface of the substrate 1100, and the inclined portion SLO may be a portion surrounding the flat portion FLT and having a surface inclined at a predetermined angle to the surface of the substrate 1100.

For example, the surface of the inclined portion SLO may not be parallel to the surface of the substrate 1100.

The first depressed portion 410 may include a first flat portion FLT1 and a first inclined portion SLO1 surrounding the first flat portion FLT1.

The second depressed portion 420 may include a second flat portion FLT2 and a second inclined portion SLO2 surrounding the second flat portion FLT2.

In one or more aspects, the insulating layer 1210 may have contact holes spaced apart from the depressed portions 400.

In one or more aspects, the first electrode 1310 may be disposed on the depressed portion 400 and the peripheral portion of the insulating layer 1210 in at least one subpixel.

As described above, in at least one subpixel, the insulating layer 1210 may include at least one contact hole spaced apart from the depressed portion 400, and the first transistor and the first electrode 1310 of a light emitting element such as an organic light emitting element, an organic light emitting diode, and the like may be electrically connected through the contact hole of the insulating layer 1210.

The bank layer 1330 may be disposed on the insulating layer 1210 and include at least one open area OPN in at least one subpixel.

The bank layer 1330 may include the open area OPN exposing a portion of the upper surface of the first electrode 1310 in an area overlapping with depressed portion 400.

The open area OPN may correspond to a portion of the flat portion FLT.

The corresponding of the open area OPN with the portion of the flat portion FLT may mean, for example, that the open area OPN overlaps with the portion of the flat portion FLT in the subpixel.

Therefore, at least one subpixel may have an area where the first electrode 1310 does not overlap with the bank layer 1330.

The at least one open area OPN may include a first open area OPN1 and a second open area OPN2.

The first open area OPN1 in the first subpixel among the plurality of subpixels may be greater (e.g., wider) than the second open area OPN2 in a second subpixel among the plurality of subpixels.

The emission layer 1320 of the light emitting element may be disposed on a portion of the first electrode 1310 not overlapping with the bank layer 1330.

This emission layer 1320 may be disposed on the first electrode 1310 and the bank layer 1330.

The second electrode 1340 of the light emitting element may be disposed on the emission layer 1320.

In one or more aspects, the emission layer 1320 of the light emitting element may be formed by a deposition or coating method having linearity.

For example, the emission layer 1320 may be formed by a physical vapor deposition method (PVD).

In an example where the emission layer 1320 is formed by this method, an area having a predetermined angle to the substrate 1100 may have a thickness less that an area parallel to the substrate 1100.

Therefore, when the light emitting element is driven, current density may be the highest in an area where the thickness of the emission layer 1320 is relatively thin, that is, in an area corresponding to the inclined portion of the depressed portion 400. Therefore, a strong electric field may be generated in the area corresponding to the inclined portion of the depressed portion 400.

Thereby, an emission characteristic of the light emitting element in the area corresponding to the inclined portion of the depressed portion 400 and an emission characteristic of the light emitting element in an area corresponding to the flat portion of the depressed portion 400 may become different from each other, and in turn, the degradation of the light emitting element may be accelerated.

In one or more aspects, the emission layer 1320 may include a red emission layer 1320R of a red subpixel R, a green emission layer 1320G of a green subpixel G, and a blue emission layer 1320B of a blue subpixel B. For example, the emission layers (1320R, 1320G, and 1320B) may be organic emission layers.

FIG. 9A illustrates the example where the red emission layer 1320R is disposed in the second subpixel and the green emission layer 1320G is disposed in the first subpixel, but aspects of the present disclosure are not necessarily limited thereto.

In one or more aspects, the bank layer 1330 may be configured to cover the inclined portion of the depressed portion 400. Thereby, the degradation acceleration of the light emitting element in the area corresponding to the inclined portion of the depressed portion 400 can be prevented, and a difference in emission characteristics between areas can be prevented.

However, thickness conditions of the emission layer 1320 according to aspects of the present disclosure are not limited to this, and the emission layer 1320 may have a respective thickness in each portion of the emission layer 1320.

In one or more aspects, the first electrode 1310 may include a reflective metal.

FIG. 9A illustrates the first electrode 1310 with a single layer, but aspects of the present disclosure are not limited thereto. The first electrode 1310 may include multiple layers.

For example, in an example where the first electrode 1310 includes multiple layers, at least one of the multiple layers may have a reflective metal.

For example, the first electrode 1310 may include at least one of aluminum (Al), neodymium (Nd), nickel (Ni), titanium (Ti), tantalum (Ta), copper (Cu), silver (Ag), and an aluminum alloy, but aspects of the present invention are not limited thereto.

The second electrode 1340 may include a conductive material transmitting or semi-transmitting light.

For example, the second electrode 1340 may include at least one of transparent conductive oxides, such as indium tin oxide (ITO), indium zinc oxide (IZO), indium tin zinc oxide (ITZO), zinc oxide, tin oxide, and the like, or include a semi-transmissive metal, such as magnesium (Mg), silver (Ag), an alloy of Mg and Ag, and the like.

For example, in an example where the second electrode 1340 includes a semi-transmissive metal, a thickness of the second electrode 1340 may be less than that of the first electrode 1310.

In one or more aspects, the first metal pattern 1127, the second metal pattern 1128 electrically connected to the first metal pattern 1127, and a third metal pattern 1129 disposed on the first insulating layer 1211 may be disposed over the substrate 1100.

The first metal pattern 1127 may serve as a capacitor or serve to shield light coming from under the first metal pattern 1127 or the substrate 1100.

The second metal pattern 1128 may contact the first metal pattern 1127 through holes in the first buffer layer 1110, the second buffer layer 1111, the first gate insulating layer 1112, the first interlayer insulating layer 1113, the third buffer layer 1114, the second gate insulating layer 1115, and the second interlayer insulating layer 1116.

The third metal pattern 1129 may contact the first source electrode layer 1123 through a hole in the first insulating layer 1211, and contact the first electrode 1310 through holes in the second insulating layer 1212 and the third insulating layer 1213.

For example, the third metal pattern 1129 can electrically interconnect the first source electrode layer 1123 and the first electrode 1310.

In one or more aspects, as shown in FIG. 9A, a storage capacitor Cst may be disposed in the active area A/A.

The storage capacitor Cst may include a first storage capacitor electrode layer 1125 disposed in the same layer as the first gate electrode layer 1122 and a second storage capacitor electrode layer 1126 disposed on the first interlayer insulating layer 1113. However, the structure of the storage capacitor according to aspects of the present disclosure is not limited to this.

As shown in FIG. 9A, the second storage capacitor electrode layer 1126 may form a capacitor with a second gate electrode layer 1131 of the second transistor different from the first transistor.

A second active layer 1130 of the second transistor may be disposed on the third buffer layer 1114.

The second gate insulating layer 1115 may be disposed on the second active layer 1130, and the second gate electrode layer 1131 may be disposed on the second gate insulating layer 1115.

The second interlayer insulating layer 1116 may be disposed on the second gate electrode layer 1131, and the insulating layer 1210 may be disposed on the second interlayer insulating layer 1116.

A second source electrode layer 1132 and a second drain electrode layer 1133 may be disposed on the second interlayer insulating layer 1116.

The second source electrode layer 1132 and the second drain electrode layer 1133 may be configured to be spaced apart from each other on the second interlayer insulating layer 1116.

The second source electrode layer 1132 and the second drain electrode layer 1133 may contact respective portions of the second active layer 1130 through holes in the second interlayer insulating layer 1116.

In one or more aspects, at least one encapsulation layer 1350 may be disposed on the second electrode 1340 of the light emitting element.

The encapsulation layer 1350 may include a first encapsulation layer 1351 disposed on the second electrode 1340, a second encapsulation layer 1352 disposed on the first encapsulation layer 1351, and a third encapsulation layer 1353 disposed on the second encapsulation layer 1352.

In an example where the encapsulation layer 1350 includes multiple layers, at least one layer among the multiple layers may include an inorganic insulating material, and at least another layer may include an organic insulating material.

For example, each of the first encapsulation layer 1351 and the third encapsulation layer 1353 may include an inorganic insulating material, and the second encapsulation layer 1352 may include an organic insulating material, but aspects of the present disclosure are not limited thereto.

The encapsulation layer 1350 disposed on the light emitting element can prevent moisture or undesirable substances or particles from penetrating into the light emitting element such as the organic light emitting element, the organic light emitting diode, and the like.

A plurality of black matrices 220 may be disposed on the third encapsulation layer 1353.

The black matrices 220 may include a material with low reflectance.

For example, the black matrices 220 may include carbon black, dye, or resin.

The touch interlayer insulating layer 1370 may be disposed on the third encapsulation layer 1353 and the black matrices 220.

A lower planarization layer 1381 may be disposed on the touch interlayer insulating layer 1370.

The lower planarization layer 1381 may be disposed adjacent to sides (or side surfaces) of a plurality of lenses LEN.

A plurality of touch sensors 210 may be disposed on the lower planarization layer 1381 and the touch interlayer insulating layer 1370.

Touch sensors 210 may be transparent or opaque.

An upper planarization layer 1382 may be disposed on the plurality of touch sensors 210.

As the upper planarization layer 1382 is configured to cover the lenses LEN, the display device can provide an advantage of producing excellent luminance by causing light trapped in the substrate 1100 by total reflection or the like to be extracted.

A refractive index of the upper planarization layer 1382 may be less than those of the plurality of lenses LEN.

As the refractive index of the upper planarization layer 1382 is less than those of the lenses LEN, traveling paths of light emitted from the light emitting element can be controlled in a desired direction.

The lenses LEN may include a first lens LEN1 corresponding to the first depressed portion 410 disposed in the first subpixel and a second lens LEN2 corresponding to the second depressed portion 420 disposed in the second subpixel.

Here, the corresponding of the lenses LEN with the depressed portions 400 may mean, for example, that each lens LEN is configured to overlap with all or a portion of the corresponding depressed portion 400 in one subpixel.

As each lens LEN is disposed in an area corresponding to the corresponding depressed portion 400, for example, light directed outside of the display device after emitted from the emission layer 1320, and light directed outside of the display device after emitted from the emission layer 1320 and reflected by the reflective metal included in the first electrode 1310 disposed in the inclined portion SLO of the depressed portion 400 can be effectively dispersed.

Since the light dispersed by the lenses LEN can be extracted outside of the display device without being totally reflected at the interface between the display device and external air, the luminance of the display device can be improved by the lenses LEN.

In one or more aspects, respective thicknesses of the first lens LEN1 and the second lens LEN2 are not particularly limited, but it may be preferable that the thickness of the second lens LEN2 is greater than the thickness of the first lens LEN1.

For example, the thickness of a lens with the largest thickness among lenses included in the second lens LEN2 may be greater than that of a lens with the largest thickness among lenses included in the first lens LEN1.

In an example where the thickness of the second lens LEN2 is greater than that of the first lens LEN1, the second lens LEN2 can be implemented as a relatively thick lens, this resulting in an advantage capable of focusing light, and the first lens LEN1 can be implemented as a relatively thin lens, this resulting in an advantage capable of including multiple lenses. Thereby, light can be randomly spread.

The thickness of the lens with the largest thickness among the lenses included in the second lens LEN2 may be greater than 2 um and less than 10 um, but aspects of the present disclosure are not limited thereto.

The thickness of the lens with the largest thickness among the lenses included in the first lens LEN1 may be 0.1 um or more and 2 um or less, but aspects of the present disclosure are not limited thereto.

Referring to FIG. 9A, color filters CF may be disposed between the touch interlayer insulating layer 1370 and the lenses (LEN1 and LEN2).

In one or more aspects, the color filters CF may be disposed in the same layer as a layer in which the lower planarization layer 1381 is disposed.

As shown in FIG. 9A, for example, a green color filter CF1 may be disposed between the touch interlayer insulating layer 1370 and the first lens LEN1, and a red color filter CF2 may be disposed between the touch interlayer insulating layer 1370 and the second lens LEN2.

As the color filters CF are disposed between the touch interlayer insulating layer 1370 and the lenses (LEN1 and LEN2), the display device can provide an advantage of having high luminance efficiency.

As shown in FIG. 9A, the green color filter CF1 and the red color filter CF2 may be disposed between the touch buffer layer 1360 and a layer in which a plurality of touch sensors 210 are disposed.

In one or more aspects, a plurality of connection patterns 1400 may be disposed in a layer in which the black matrices 220 are disposed.

The connection patterns 1400 may include a first connection pattern 1410 disposed on the touch buffer layer 1360 and a second connection pattern 1420 electrically connected to at least one of the plurality of touch sensors 210.

The first connection pattern 1410 and the second connection pattern 1420 may be contacted through a hole formed in the touch interlayer insulating layer 1370.

At least one dam 1500 may be disposed outside of the upper planarization layer 1382.

For example, the display device may include a first dam 1510 disposed outside of the encapsulation layer 1350 and a second dam 1520 disposed outside of the upper planarization layer 1382.

Herein, the first dam 1510 and the second dam 1520 may mean, for example, a lower dam and an upper dam, respectively.

FIG. 9A illustrates an example where the first dam 1510 and the second dam 1520 are disposed over the substrate 1100, but aspects of the present disclosure are not limited thereto. For example, the number of dams 1500 disposed over the substrate 1100 may be appropriately changed depending on the size of the display device or other requirements.

In one or more aspects, FIG. 9A illustrates an example where the first dam 1510 has two partitions and the second dam 1520 has one partition, but aspects of the present disclosure are not limited thereto. For example, each dam may be configured with multiple partitions.

Since the upper planarization layer 1382 disposed to flatten the lenses LEN is formed by inkjet printing, by disposing the second dam 1520, ink can be prevented from leaking out outside of the first dam 1510 during the inkjet printing.

In one or more aspects, one or more touch lines 300 may be disposed on the touch interlayer insulating layer 1370.

Two or more touch sensors 210 may be electrically connected to each other through one or more connection patterns 1400 and thereby, may form one driving touch electrode line or one sensing touch electrode line.

FIG. 9A illustrates that the touch sensors 210 and the touch line 300 are disposed in the same layer, but aspects of the present disclosure are not limited thereto. For example, the touch sensors 210 and the touch line 300 may be disposed in different layers.

The touch line 300 may be disposed on the first dam 1510 and extend to a pad 500 disposed outside of the first dam 1510 and including conductive pads.

The touch line 300 may be electrically connected to the pad 500.

For example, the touch line 300 may be electrically connected to a corresponding one of conductive pads included in the pad 500 disposed in the non-active area.

The conductive pad of the pad 500 to which the touch line 300 is connected may be connected to a touch sensing circuit (not shown).

The touch sensing circuit (not shown) can supply a touch driving signal to at least one of a plurality touch sensors 200, and detect whether a touch is applied and/or a location of the touch (or touch coordinates) in response to the touch driving signal.

The touch line 300, the touch interlayer insulating layer 1370, the touch buffer layer 1360, and the encapsulation layer 1350 may be disposed on the first dam 1510 and configured to overlap with the first dam 1500, but aspects of the present disclosure are not limited thereto.

A passivation layer 1390 may be disposed on the planarization layer 1380 and the second dam 1520.

The passivation layer 1390 can prevent moisture or undesirable substances or particles from penetrating and prevent materials such as metal from corroding by reacting with moisture in the air.

FIG. 9B is an example cross-sectional view taken along line A-A′ of FIG. 4 according to another aspect of the present disclosure.

It should be noted that respective configurations of touch sensors 210, black matrices 220, a touch line 300, a first depressed portion 410, a second depressed portion 420, a pad 500, a first lens LEN1, a second lens EN2, a first open area OPN1, a second open area OPN2, a substrate 1100, a first buffer layer 1110, a second buffer layer 1111, a first gate insulating layer 1112, a first interlayer insulating layer 1113, a third buffer layer 1114, a second gate insulating layer 1115, a second interlayer insulating layer 1116, a first active layer 1121, a first gate electrode layer 1122, a first source electrode layer 1123, a first drain electrode layer 1124, a first storage capacitor electrode layer 1125, a second storage capacitor electrode layer 1126, a first metal pattern 1127, a second metal pattern 1128, a third metal pattern 1129, a second active layer 1130, a second gate electrode layer 1131, a second source electrode layer 1132, a second drain electrode layer 1133, an insulating layer 1210, a first insulating layer 1211, a second insulating layer 1212, a third insulating layer 1213, a first electrode layer 1310, an emission layer 1320, a bank layer 1330, a second electrode layer 1340, an encapsulation layer 1350, a first encapsulation layer 1351, a second encapsulation layer 1352, a third encapsulation layer 1353, a touch buffer layer 1360, a touch interlayer insulating layer 1370, a lower planarization layer 1381, an upper planarization layer 1382, a passivation Layer 1390, connection patterns 1400, a first connection pattern 1410, a second connection pattern 1420, a first dam 1510, a second dam 1520, a first flat portion FLT1, a second flat portion FLT2, a first inclined portion SLO1, and a second inclined portion SLO2 illustrated in FIG. 9B may be substantially the same as the respective configurations of the touch sensors 210, the black matrices 220, the touch line 300, the first depressed portion 410, the second depressed portion 420, the pad 500, the first lens LEN1, the second lens LEN2, the first open area OPN1, the second open area OPN2, the substrate 1100, the first buffer layer 1110, the second buffer layer 1111, the first gate insulating layer 1112, the first interlayer insulating layer 1113, the third buffer layer 1114, the second gate insulating layer 1115, the second interlayer insulating layer 1116, the first active layer 1121, the first gate electrode layer 1122, the first source electrode layer 1123, the first drain electrode layer 1124, the first storage capacitor electrode layer 1125, the second storage capacitor electrode layer 1126, the first metal pattern 1127, the second metal pattern 1128, the third metal pattern 1129, the second active layer 1130, the second gate electrode layer 1131, the second source electrode layer 1132, the second drain electrode layer 1133, the insulating layer 1210, the first insulating layer 1211, the second insulating layer 1212, the third insulating layer 1213, the first electrode layer 1310, the emission layer 1320, the bank layer 1330, the second electrode layer 1340, the encapsulation layer 1350, the first encapsulation layer 1351, the second encapsulation layer 1352, the third encapsulation layer 1353, the touch buffer layer 1360, the touch interlayer insulating layer 1370, the lower planarization layer 1381, the upper planarization layer 1382, the passivation layer 1390, the connection patterns 1400, the first connection pattern 1410, the second connection pattern 1420, the first dam 1510, the second dam 1520, the first flat portion FLT1, the second flat portion FLT2, the first inclined portion SLO1, and the second inclined portion SLO2 illustrated in FIG. 9A discussed above.

Referring to FIG. 9B, a first color filter CF1 may be disposed between at least one first lens among a plurality of lenses LEN and the upper planarization layer 1382.

The first color filter CF1 may include a lower color filter CF1b disposed on a touch sensor 210 and overlapping with at least a portion of the first lens LEN1, and an upper color filter CF1a disposed on the lower color filter CF1b and covering the first lens LEN1.

Since the first color filter CF1 covers at least a portion of the touch sensor 210, the amount of light reflected by the touch sensor 210 can be reduced.

In one or more aspects, referring to FIG. 9B, the second lens LEN2, which is at least one of the plurality of lenses LEN, may be a second color filter CF2.

For example, the second color filter CF2 may be implemented in the form of a lens.

For example, the second color filter CF2 as shown in FIG. 9B may be referred to as a color lens.

Since the second color filter CF2 serve as the second lens LEN2, the number of processes can be reduced, and thereby, the manufacturing process can be optimized.

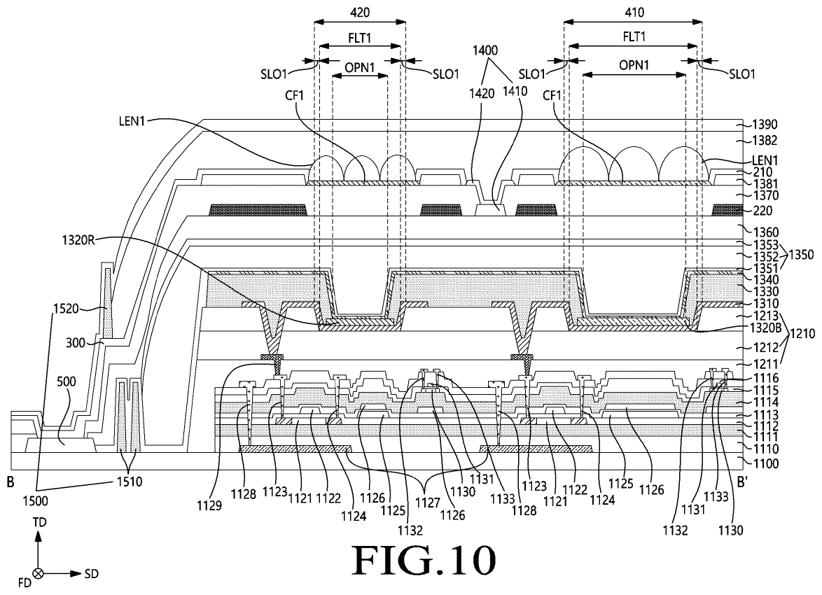

FIG. 10 is an example cross-sectional view taken along with line B-B′ of FIG. 5 according to aspects of the present disclosure.

It should be noted that respective configurations of touch sensors 210, black matrices 220, a touch line 300, a first depressed portion 410, a pad 500, a first open area OPN1, a substrate 1100, a first buffer layer 1110, a second buffer layer 1111, a first gate insulating layer 1112, a first interlayer insulating layer 1113, a third buffer layer 1114, a second gate insulating layer 1115, a second interlayer insulating layer 1116, a first active layer 1121, a first gate electrode layer 1122, a first source electrode layer 1123, a first drain electrode layer 1124, a first storage capacitor electrode layer 1125, a second storage capacitor electrode layer 1126, a first metal pattern 1127, a second metal pattern 1128, a third metal pattern 1129, a second active layer 1130, a second gate electrode layer 1131, a second source electrode layer 1132, a second drain electrode layer 1133, an insulating layer 1210, a first insulating layer 1211, a second insulating layer 1212, a third insulating layer 1213, a first electrode layer 1310, an emission layer 1320, a bank layer 1330, a second electrode layer 1340, an encapsulation layer 1350, a first encapsulation layer 1351, a second encapsulation layer 1352, a third encapsulation layer 1353, a touch buffer layer 1360, a touch interlayer insulating layer 1370, a lower planarization layer 1381, an upper planarization layer 1382, a passivation Layer 1390, connection patterns 1400, a first connection pattern 1410, a second connection pattern 1420, a first dam 1510, a second dam 1520, a first flat portion FLT1, a first inclined portion SLO1, and a first color filter CF1 illustrated in FIG. 10 may be substantially the same as the respective configurations of the touch sensors 210, the black matrices 220, the touch line 300, the first depressed portion 410, the pad 500, the first open area OPN1, the substrate 1100, the first buffer layer 1110, the second buffer layer 1111, the first gate insulating layer 1112, the first interlayer insulating layer 1113, the third buffer layer 1114, the second gate insulating layer 1115, the second interlayer insulating layer 1116, the first active layer 1121, the first gate electrode layer 1122, the first source electrode layer 1123, the first drain electrode layer 1124, the first storage capacitor electrode layer 1125, the second storage capacitor electrode layer 1126, the first metal pattern 1127, the second metal pattern 1128, the third metal pattern 1129, the second active layer 1130, the second gate electrode layer 1131, the second source electrode layer 1132, the second drain electrode layer 1133, the insulating layer 1210, the first insulating layer 1211, the second insulating layer 1212, the third insulating layer 1213, the first electrode layer 1310, the emission layer 1320, the bank layer 1330, the second electrode layer 1340, the encapsulation layer 1350, the first encapsulation layer 1351, the second encapsulation layer 1352, the third encapsulation layer 1353, the touch buffer layer 1360, the touch interlayer insulating layer 1370, the lower planarization layer 1381, the upper planarization layer 1382, the passivation layer 1390, the connection patterns 1400, the first connection pattern 1410, the second connection pattern 1420, the first dam 1510, the second dam 1520, the first flat portion FLT1, the first inclined portion SLO1, and the first color filter CF1 illustrated in FIG. 9A discussed above.

Referring to FIG. 10, the first lens LEN1 may be disposed on the first color filter CF1 and may include three lenses corresponding to the first depressed portion 410.

FIG. 10 illustrates that the first lens LEN1 includes three lenses, but aspects of the present disclosure are not necessarily limited thereto. For example, the number of lenses included in the first lens LEN1 may one, two, or four or more.

In one or more aspects, the first color filter CF1 may be disposed between the first lens LEN1 and the touch interlayer insulating layer 1370.

Referring to FIG. 10, the refractive index of the upper planarization layer 1382 may be less than the refractive index of the first lens LEN1.

In an example where the refractive index of the upper planarization layer 1382 is less than the refractive index of the first lens LEN1, light extraction efficiency can be increased by the first lens LEN1.

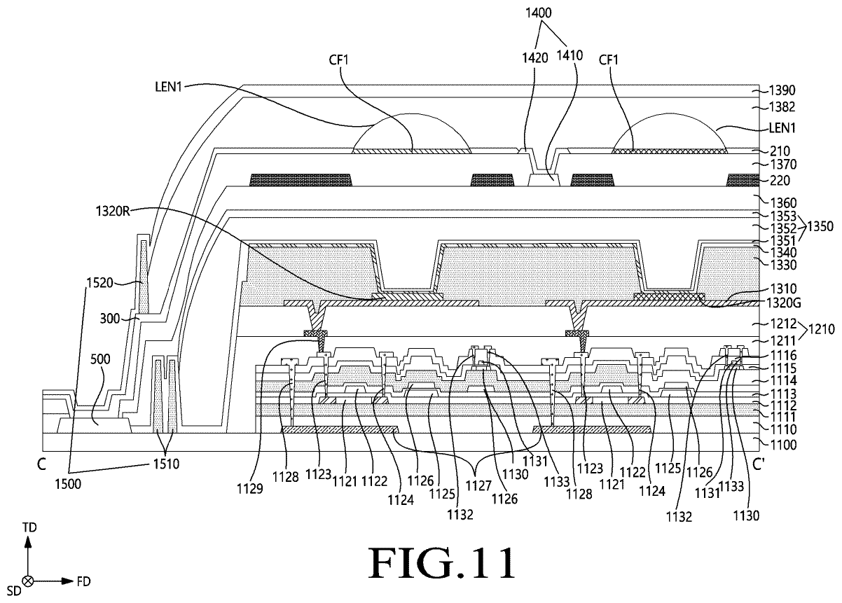

FIG. 11 is an example cross-sectional view taken along line C-C′ of FIG. 5 according to aspects of the present disclosure.

It should be noted that respective configurations of touch sensors 210, black matrices 220, a touch line 300, a pad 500, a substrate 1100, a first buffer layer 1110, a second buffer layer 1111, a first gate insulating layer 1112, a first interlayer insulating layer 1113, a third buffer layer 1114, a second gate insulating layer 1115, a second interlayer insulating layer 1116, a first active layer 1121, a first gate electrode layer 1122, a first source electrode layer 1123, a first drain electrode layer 1124, a first storage capacitor electrode layer 1125, a second storage capacitor electrode layer 1126, a first metal pattern 1127, a second metal pattern 1128, a third metal pattern 1129, a second active layer 1130, a second gate electrode layer 1131, a second source electrode layer 1132, a second drain electrode layer 1133, an insulating layer 1210, a first insulating layer 1211, a second insulating layer 1212, a third insulating layer 1213, a first electrode layer 1310, an emission layer 1320, a bank layer 1330, a second electrode layer 1340, an encapsulation layer 1350, a first encapsulation layer 1351, a second encapsulation layer 1352, a third encapsulation layer 1353, a touch buffer layer 1360, a touch interlayer insulating layer 1370, an upper planarization layer 1382, a passivation Layer 1390, connection patterns 1400, a first connection pattern 1410, a second connection pattern 1420, a first dam 1510, a second dam 1520, and a first color filter CF1 illustrated in FIG. 11 may be substantially the same as the respective configurations of the touch sensors 210, the black matrices 220, the touch line 300, the pad 500, the substrate 1100, the first buffer layer 1110, the second buffer layer 1111, the first gate insulating layer 1112, the first interlayer insulating layer 1113, the third buffer layer 1114, the second gate insulating layer 1115, the second interlayer insulating layer 1116, the first active layer 1121, the first gate electrode layer 1122, the first source electrode layer 1123, the first drain electrode layer 1124, the first storage capacitor electrode layer 1125, the second storage capacitor electrode layer 1126, the first metal pattern 1127, the second metal pattern 1128, the third metal pattern 1129, the second active layer 1130, the second gate electrode layer 1131, the second source electrode layer 1132, the second drain electrode layer 1133, the insulating layer 1210, the first insulating layer 1211, the second insulating layer 1212, the third insulating layer 1213, the first electrode layer 1310, the emission layer 1320, the bank layer 1330, the second electrode layer 1340, the encapsulation layer 1350, the first encapsulation layer 1351, the second encapsulation layer 1352, the third encapsulation layer 1353, the touch buffer layer 1360, the touch interlayer insulating layer 1370, the upper planarization layer 1382, the passivation layer 1390, the connection patterns 1400, the first connection pattern 1410, the second connection pattern 1420, the first dam 1510, the second dam 1520, and the first color filter CF1 illustrated in FIG. 9A discussed above.

Referring to FIG. 11, a first lens LEN1 corresponding to the emission layer 1320 may be disposed on the touch interlayer insulating layer 1370.

The first color filter layer CF1 may be disposed between the first lens LEN1 and the touch interlayer insulating layer 1370.

As shown in FIG. 11, when a lower planarization layer and a depressed portion are not included in the first direction FD, the performance of the display device 100 in a wide viewing angle mode can be maximized.

In one or more examples, an area of a first depressed portion may be greater than an area of a second depressed portion. For example, referring to FIGS. 8A to 10, an area of a first depressed portion 410 may be greater than an area of a second depressed portion 420. In an example, an area of the first depress portion 410 may be a total area of the first depress portion 410 (including the flat portion FLT1 and the inclined portion SLO1) when viewed in a plane defined in the first direction FD and the second direction SD. In an example, an area of the second depressed portion 420 may be a total area of the second depressed portion 420 (including the flat portion FLT2 and the inclined portion SLO2) when viewed in a plane defined in the first direction FD and the second direction SD.

In one or more examples, an area of the first lens may be greater than an area of the second lens. For example, referring to FIGS. 4 to 10, an area of the first lens LEN1 may be greater than an area of the second lens LEN2. In an example, an area of the first lens LEN1 may be a total area defined by the first lens LEN1 (or a bottom surface of the first lens LEN1) when viewed in a plane defined in the first direction FD and the second direction SD. In an example, an area of the second lens LEN2 may be a total area defined by the second lens LEN2 (or a bottom surface of the second lens LEN2) when viewed in a plane defined in the first direction FD and the second direction SD. In an example, referring to FIG. 7A, an area of the first lens LEN1 may be an area defined by a diameter C1 and a diameter C2 (e.g., C1×C2). In an example, referring to FIG. 7B, an area of the first lens LEN1 may be an area defined by a sum of (i) an area of a first micro lens LEN1a, (ii) an area of a second micro lens LEN1b, and (iii) an area of a third micro lens LEN1c. In this example, each of the first, second and third micro lens LEN1a, LEN1b, and LEN1c has a diameter of C1. Hence, in this example, the area can be 3×π×(C1/2)². In an example, referring to FIG. 7C, an area of the second lens LEN2 can be an area defined by a diameter S1 and a diameter S2.

With respect to FIGS. 7A to 7C, in one or more examples, a thickness of the first lens LEN1 may be the largest thickness of one or more lenses included in the first lens LEN1. In an example, a thickness of a first lens LEN1 of FIG. 7A may be a height C3. In an example, a thickness of a first lens LEN1 of FIG. 7B may be a height C3. Further, a thickness of the second lens LEN2 may be the largest thickness of one or more lenses included in the second lens LEN2. In an example, a thickness of a second lens LEN2 of FIG. 7C may be a height S3.

With respect to FIGS. 8A, 9A and 9B, in one or more examples, a first planarization layer 610 surrounding a first lens LEN1, as illustrated in FIG. 8A, may correspond to or may be substantially the same as a lower planarization layer 1381 surrounding a first lens LEN1, as illustrated in FIGS. 9A and 9B.

With respect to FIGS. 8B, 9A and 9B, in one or more examples, a second planarization layer 620 surrounding a second lens LEN2, as illustrated in FIG. 8B may be similar to a lower planarization layer 1381 surrounding a second lens LEN2, as illustrated in FIGS. 9A and 9B.

With respect to FIGS. 8C and 10, in one or more examples, a first planarization layer 610 surrounding a second lens LEN1, as illustrated in FIG. 8C may correspond to or may be substantially the same as a lower planarization layer 1381 surrounding a first lens LEN1, as illustrated in FIG. 10.

Various examples and aspects of the present disclosure are described below. These are provided as examples, and do not limit the scope of the present disclosure.

In connection with FIGS. 1A to 11, in one or more aspects, the display device 100 may be, may be included in, or may include, a foldable device. A foldable device may refer to, or may be, a foldable display device, a rollable device, a bendable device, a flexible device, a stretchable device, a curved device, a sliding device, or a variable device, and vice versa. The display device 100 according to one or more aspects of the present disclosure may be, or may be included in, a mobile terminal (e.g., a smart phone, a video phone, a smart watch, a watch phone, a wearable device, a tablet, an electronic notebook, a notebook computer, a netbook computer, an e-book, a portable multimedia player (PMP), a personal digital assistant (PDA), an MPEG-1 Audio Layer 3 (MP3) player, a mobile medical device, a laptop, or the like), a desktop personal computer (PC), a workstation, a navigation device, a car navigation device, a vehicle display device, a vehicle apparatus, a theater apparatus, a theater display device, a television, a wallpaper device, a signage device, a gaming device, a monitor, a camera, a sensor, a camcorder, or a home appliance, or the like. The display device 100 according to one or more aspects of the present disclosure are not limited to the foregoing example devices. The display device 100 according to one or more aspects of the present disclosure may be made in various types, sizes, and shapes that are configured to display information and/or images.

In connection with FIGS. 1A to 11, in one or more aspects, when the display device 100 is a foldable device, a foldable area may be formed around a folding axis. In an example, the foldable area may overlap a portion of the active area A/A and/or a portion of the non-active area. The foldable area may be an area that is folded with a predefined curvature when the foldable device is folded in at least one scheme among inner folding and outer folding. An area other than the foldable area may be a non-foldable area. A foldable area may include one or more foldable areas. Moreover, when the display device 100 is the foldable device, in some examples, the display device may further include a hinge structure for folding a display panel or the like, and a casing for supporting and accommodating the display panel or the like. In one or more examples, when the display device 100 is the foldable device, the substrate of the display device may be a multilayer substrate, and the substrate may be flexible.

In connection with FIGS. 1A to 11, in one or more aspects, the substrate 1100 of the display device 100 may serve to support and protect constituent elements of the display device 100 that are disposed above the substrate 1100. The substrate 1100 is a component for supporting various constituent elements included in the display device 100 and may be made of one or more insulating materials. The substrate 1100 may be a multilayer substrate (e.g., a triple-layer substrate), including, for example, a first substrate, a second substrate, and an inorganic insulation layer. The inorganic insulation layer may be disposed between the first substrate and the second substrate. The substrate, being multilayer, can minimize moisture penetration from the outside. In another example, the substrate 1100 may be disposed as a single layer.

The first substrate may have rigidity and flexibility. Among the components of the substrate 1100, the first substrate may be configured to substantially support the constituent elements of the display device 100. For example, the first substrate may be a flexible substrate made of polyimide (PI). However, the present disclosure is not limited thereto.

The inorganic insulation layer may be disposed on an entire surface of the first substrate. The inorganic insulation layer may be made of an inorganic insulating material. For example, the inorganic insulation layer may be configured as a single layer or multilayer made of silicon nitride (SiNx) or silicon oxide (SiOx). However, the present disclosure is not limited thereto.

The second substrate may be disposed on the inorganic insulation layer. The second substrate may have rigidity and flexibility. Among the components of the substrate 1100, the second substrate, together with the first substrate, may be configured to substantially support the constituent elements of the display device 100. For example, the second substrate may be a flexible substrate made of polyimide (PI). However, the present disclosure is not limited thereto.

Various examples and aspects of the present disclosure are described further below. These are provided as examples, and do not limit the scope of the present disclosure. The figure numbers and reference numerals identified below are non-limiting examples for illustration purposes only and do not limit the scope of the present disclosure. The present disclosure covers not only the examples illustrated herein but also various modifications and variations, and the features or principles described herein may be applied to such modifications and variations without departing from the scope of the present disclosure. The notation “e.g.” represents “for example without limitation”.

According to one or more aspects of the present disclosure, a display device (e.g., 100; or a variation(s)) may include: a first emission layer (e.g., an emission layer of SP1 or SP3 of FIG. 8A or 8C; 1320 or 1320G; or a variation(s)); and a second emission layer (e.g., an emission layer of SP2; 1320 or 1320R; or a variation(s)). In a first mode, the display device may be configured to emit light from the first emission layer and prevent emitting light from the second emission layer; and in a second mode, the display device may be configured to emit light from the second emission layer and prevent emitting light from the first emission layer. In the first mode, the light from the first emission layer may provide (a) a first viewing angle in a first direction (e.g., SD; or a variation(s)) and (b) a second viewing angle in a second direction (e.g., FD; or a variation(s)); and in the second mode, the light from the second emission layer may provide (a) one viewing angle in one direction (e.g., SD; or a variation(s)) and (b) another viewing angle in another direction (e.g., FD; or a variation(s)). The second emission layer may be different from the first emission layer; the second mode may be different from the first mode; the second direction may be different from the first direction; the another direction may be different from the one direction; and a range of the first viewing angle may be greater than a range of each of the second viewing angle, the one viewing angle, and the another viewing angle.

In one or more examples, the first mode may be a wide viewing angle mode. In one or more examples, the first mode may be a shared mode. In one or more examples, the first mode may be a public mode.

In one or more examples, the second mode may be a narrow viewing angle mode. In one or more examples, the second mode may be a privacy mode. In one or more examples, the second mode may be a private mode.

In one or more examples, the display device may include: a first light emitting area (e.g., OPN1; or a variation(s)); and a second light emitting area (e.g., OPN2; or a variation(s)). The first emission layer may correspond to the first light emitting area; the second emission layer may correspond to the second light emitting area; and the second light emitting area may be separate and different from the first light emitting area.

In one or more examples, the display device may include: one or more first structures (see, e.g., structure(s) formed from 1210 or its component(s) and/or 1381; structure(s) formed from 410 and/or 610; or a variation(s)) corresponding to the first emission layer; and one or more second structures (see, e.g., structure(s) formed from 1210 or its component(s) and/or 1381; structure(s) formed from 410 and/or 610; or a variation(s)) corresponding to the second emission layer. The one or more first structures may be disposed adjacent to the first emission layer (or at least a portion of the first emission layer) in a plan view; and the one or more second structures may be disposed adjacent to the second emission layer (or at least a portion of the second emission layer) in a plan view. In the first mode, the one or more first structures may be configured to adjust the light from the first emission layer and to cause the range of the first viewing angle to be greater than the range of the second viewing angle; and in the second mode, the one or more second structures may be configured to adjust the light from the second emission layer and to cause the range of each of the one viewing angle and the another viewing angle to be less than the range of the first viewing angle.

In one or more examples, the one or more first structures may include one or more structures that can adjust the light (e.g., direct, redirect, absorb, block, expand, spread, scatter, alter, control, manipulate, pass, reflect, or guide the light) to cause the range of the first viewing angle to be greater than the range of the second viewing angle.

In one or more examples, the one or more second structures may include one or more structures that can adjust the light (e.g., direct, redirect, absorb, block, expand, spread, scatter, alter, control, manipulate, pass, reflect, or guide the light) to cause the range of each of the one viewing angle and the another viewing angle to be less than the range of the first viewing angle.

In one or more examples, the one or more first structures may be located at least above, at or below a position of the at least a portion of the first emission layer in a cross-sectional view. In one or more examples, the one or more first structures (or at least a portion thereof) may be located above the position of the first emission layer (or at least a portion thereof) in a cross-sectional view. In one or more examples, the one or more first structures (or at least a portion thereof) may be located above the lowest position of the first emission layer (or at least a portion thereof) in a cross-sectional view.

In one or more examples, the one or more second structures may be located at least above, at or below a position of the at least a portion of the second emission layer in a cross-sectional view. In one or more examples, the one or more second structures (or at least a portion thereof) may be located above the position of the second emission layer (or at least a portion thereof) in a cross-sectional view. In one or more examples, the one or more second structures (or at least a portion thereof) may be located above the lowest position of the second emission layer (or at least a portion thereof) in a cross-sectional view.

In one or more examples, the one or more first structures may partially surround the at least a portion of the first emission layer in a plan view; and the one or more second structures may surround all four sides of the at least a portion of the second emission layer in a plan view.

In one or more examples, the one or more first structures may partially surround the first emission layer in a plan view; and the one or more second structures may surround all four sides of the second emission layer in a plan view.

In one or more examples, the one or more first structures may be present at at least one side of the first light emitting area in one of the first and second directions (e.g., one of FD and SD; or a variation(s)) and may be absent from at least another side of the first light emitting area in another one of the first and second directions (e.g., another one of FD and SD; or a variation(s)); and the one or more second structures may be present at sides of the second light emitting area in the one direction and the another direction (e.g., FD and SD; or a variation(s)).

In one or more examples, the one or more first structures may be present at at least one side of the first light emitting area in one of the first and second directions, and one or more other structures (see, e.g., structure(s) formed from 1210, 1330 and/or 210; or a variation(s)) may be present at at least another side of the first light emitting area in another one of the first and second directions; and the one or more second structures may be present at sides of the second light emitting area in the one direction and the another direction.

In one or more examples, the one or more first structures may include at least one of a first layer and a second layer; the one or more second structures may include at least one of a third layer and a fourth layer; the first layer may be formed of a same layer as an insulating layer (e.g., 1210 or 1213; or a variation(s)); the second layer may be formed of a same layer as a planarization layer (e.g., 1381; or a variation(s)); the third layer may be formed of a same layer as the insulating layer; the fourth layer may be formed of a same layer as the planarization layer; the second layer may be disposed above the first layer; and the fourth layer may be disposed above the third layer.

In one or more examples, the first light emitting area may be larger than the second light emitting area; each of the first light emitting area and the second light emitting area may have a polygonal shape (see, e.g., the shapes in FIGS. 8A-8C; or a variation(s)); the one direction may be same as the first direction; the another direction may be same as the second direction; and the second direction may be perpendicular to the first direction.

In one or more examples, a mode of the display device is switchable between the first mode and the second mode.

According to one or more aspects of the present disclosure, a display device may include: a first light emitting area; and a second light emitting area. In a first mode, the display device may be configured to emit light from the first light emitting area and prevent emitting light from the second light emitting area; and in a second mode, the display device may be configured to emit light from the second light emitting area and prevent emitting light from the first light emitting area. In the first mode, the light from the first light emitting area may provide (a) a first viewing angle in a first direction and (b) a second viewing angle in a second direction; and in the second mode, the light from the second light emitting area may provide (a) one viewing angle in one direction and (b) another viewing angle in another direction. The second light emitting area may be different from the first light emitting area; the second mode may be different from the first mode; the second direction may be different from the first direction; the another direction may be different from the one direction; and a range of the first viewing angle may be greater than a range of each of the second viewing angle, the one viewing angle, and the another viewing angle.

In one or more examples, the display device may include: a first emission layer corresponding to the first light emitting area; and a second emission layer corresponding to the second light emitting area. The second emission layer may be separate and different from the first emission layer.

In one or more examples, the first light emitting area may be, may represent, or may correspond to, an area of the first emission layer that is configured to emit light. In some examples, the first light emitting area may be, may represent, or may correspond to, an area of the first emission layer that is in direct contact with a first electrode layer. In some examples, the first light emitting area may be, may represent, or may correspond to, the first open area. In some examples, the first light emitting area may be, may represent, or may correspond to, a region including the first open area. In some examples, the first light emitting area may be, may represent, or may correspond to, a region including the first open area and the first inclined portion. In one or more examples, the second light emitting area may be, may represent, or may correspond to, an area of the second emission layer that is configured to emit light. In some examples, the second light emitting area may be, may represent, or may correspond to, an area of the second emission layer that is in direct contact with a first electrode layer. In some examples, the second light emitting area may be, may represent, or may correspond to, the second open area. In some examples, the second light emitting area may be, may represent, or may correspond to, a region including the second open area. In some examples, the second light emitting area may be, may represent, or may correspond to, a region including the second open area and the second inclined portion.

In one or more examples, the display device may include: one or more first structures corresponding to the first light emitting area; and one or more second structures corresponding to the second light emitting area. The one or more first structures may be disposed adjacent to the first light emitting area in a plan view; the one or more second structures may be disposed adjacent to the second light emitting area in a plan view; in the first mode, the one or more first structures may be configured to adjust the light from the first light emitting area and to cause the range of the first viewing angle to be greater than the range of the second viewing angle; and in the second mode, the one or more second structures may be configured to adjust the light from the second light emitting area and to cause the range of each of the one viewing angle and the another viewing angle to be less than the range of the first viewing angle.

In one or more examples, the one or more first structures may partially surround the first light emitting area in a plan view; and the one or more second structures may surround all four sides of the second light emitting area in a plan view.

Various examples and aspects of the present disclosure are described further below. These are provided as examples, and do not limit the scope of the present disclosure.

According to one or more example embodiments of the present disclosure, a display device may include: a first light emitting area; a second light emitting area; a first depressed portion corresponding to the first light emitting area; a second depressed portion corresponding to the second light emitting area; a first lens corresponding to the first depressed portion; and a second lens corresponding to the second depressed portion. An area of the first depressed portion may be greater than an area of the second depressed portion, and an area of the first lens may be greater than an area of the second lens.

In one or more example embodiments, a total number of lenses included in the first lens may be greater than a total number of lenses included in the second lens.

In one or more example embodiments, a shape of the first lens may be different from a shape of the second lens.

In one or more example embodiments, in a wide viewing angle mode, the display device may be configured to enable the first light emitting area to emit light and configured to prevent the second light emitting area from emitting light. In a narrow viewing angle mode, the display device may be configured to enable the second light emitting area to emit light and configured to prevent the first light emitting area from emitting light. A viewing angle in the wide viewing angle mode may be greater than a viewing angle in the narrow viewing angle mode.

In one or more example embodiments, the first lens may overlap with at least a portion of the first depressed portion, and the second lens may overlap with at least a portion of the second depressed portion.

In one or more example embodiments, a largest thickness of one or more lenses included in the first lens may be greater than a largest thickness of one or more lenses included in the second lens.

In one or more example embodiments, the first light emitting area may be represented by, or may correspond to, a first open area (and vice versa), the second light emitting area may be represented by, or may correspond to, a second open area (and vice versa), and the first open area may be greater than the second open area.

In one or more example embodiments, an inclined portion of the first depressed portion may surround at least a portion of the first open area along one direction, and an inclined portion of the second depressed portion may completely surround the second open area along at least two directions.

In one or more example embodiments, the first lens may cover at least a portion of the first open area and may cover at least a portion of the first depressed portion, and the second lens may cover at least a portion of the second open area and may cover at least a portion of the second depressed portion.

In one or more example embodiments, a shape of the first lens may correspond to a shape of the first open area, a shape of the second lens may correspond to a shape of the second open area, and the shape of the second open area may be different from the shape of the first open area.

In one or more example embodiments, the display device may include a bank layer that overlaps at least a portion of the first depressed portion and at least a portion of the first lens. The first open area may include an opening in the bank layer, and the first open area may overlap with the first depressed portion.

In one or more example embodiments, the first depressed portion may include a first flat portion and a first inclined portion, and the first inclined portion may surround at least a portion of the first flat portion.

In one or more example embodiments, one or more insulating layers may include the first flat portion and the first inclined portion.

In one or more example embodiments, the display device may include a first light emitting element corresponding to the first light emitting area, and the first light emitting element may include a first electrode, an emission layer, and a second electrode.

In one or more example embodiments, the first electrode may be disposed on the first flat portion, the first inclined portion, and a peripheral portion of the one or more insulating layers, the peripheral portion of the one or more insulating layers surrounds the first depressed portion and is located around the first depressed portion, and the emission layer may be disposed on the first electrode and may overlap the first flat portion.

In one or more example embodiments, the display device may include a bank layer that overlaps the first inclined portion and the peripheral portion of the one or more insulating layers, and the second electrode may be disposed on the emission layer and the bank layer.

In one or more example embodiments, the emission layer may overlap the first inclined portion, the emission layer may have a first thickness in an area overlapping the first flat portion, the emission layer may have a second thickness in an area overlapping the first inclined portion, and the second thickness may be less than the first thickness.

In one or more example embodiments, the first inclined portion may surround the first flat portion along a first direction, and the first inclined portion does not surround the first flat portion along a second direction.

In one or more example embodiments, the second depressed portion may include a second flat portion and a second inclined portion, and the second inclined portion may completely surround the second flat portion along two directions.

In one or more example embodiments, the display device may include a first planarization layer that surrounds at least a portion of the first lens.

In one or more example embodiments, the first planarization layer may surround at least side surfaces of the first lens along a first direction, and the first planarization layer does not surround side surfaces of the first lens along a second direction.

In one or more example embodiments, the first planarization layer may surround the second lens along the first direction and the second direction.

In one or more example embodiments, the display device may include a second planarization layer that covers the first lens, and a refractive index of the second planarization layer may be less than a refractive index of the first lens.

In one or more example embodiments, the display device may include a touch interlayer insulating layer disposed below the first planarization layer, and a first color filter disposed between the first lens and the touch interlayer insulating layer.

In one or more example embodiments, the display device may include a first color filter disposed between the second planarization layer and the first lens.

In one or more example embodiments, the display device may include: a touch sensor disposed on the first planarization layer; and a second color filter disposed on the touch sensor and overlapping with at least a part of the first lens. The first color filter may be disposed on the second color filter and covering the first lens.

In one or more example embodiments, the second lens may be a color filter.

In one or more example embodiments, a subpixel having the first depressed portion and the first lens is associated with a first color, and a subpixel having the second depressed portion and the second lens is associated with the same first color.

In one or more example embodiments, the display device may include: a touch sensor; and a first color filter disposed on the touch sensor.

In one or more example embodiments, the first color filter may be disposed on the first lens.

In one or more example embodiments, the display device may include a second color filter. Both the first color filter and the second color filter may overlap the touch sensor. Both the first color filter and the second color filter may be disposed on the touch sensor.

According to one or more example embodiments of the present disclosure, a display device may include: a first emission layer; and a second emission layer. In a first mode, the display device may be configured to emit light from the first emission layer and prevent emitting light from the second emission layer; and in a second mode, the display device may be configured to emit light from the second emission layer and prevent emitting light from the first emission layer. In the first mode, the light from the first emission layer may provide (a) a first viewing angle in a first direction and (b) a second viewing angle in a second direction; and in the second mode, the light from the second emission layer may provide (a) one viewing angle in one direction and (b) another viewing angle in another direction. The second emission layer may be different from the first emission layer; the second mode may be different from the first mode; the second direction may be different from the first direction; the another direction may be different from the one direction; and a range of the first viewing angle may be greater than a range of each of the second viewing angle, the one viewing angle, and the another viewing angle.

In one or more example embodiments, the display device may include: a first light emitting area; and a second light emitting area. The first emission layer may correspond to the first light emitting area; the second emission layer may correspond to the second light emitting area; and the second light emitting area may be separate and different from the first light emitting area.

In one or more example embodiments, the display device may include: one or more first structures corresponding to the first emission layer; and one or more second structures corresponding to the second emission layer. The one or more first structures may be disposed adjacent to at least a portion of the first emission layer in a plan view; the one or more second structures may be disposed adjacent to at least a portion of the second emission layer in a plan view; in the first mode, the one or more first structures may be configured to adjust the light from the first emission layer and to cause the range of the first viewing angle to be greater than the range of the second viewing angle; and in the second mode, the one or more second structures may be configured to adjust the light from the second emission layer and to cause the range of each of the one viewing angle and the another viewing angle to be less than the range of the first viewing angle.

In one or more example embodiments, the one or more first structures may be present at at least one side of the first light emitting area in one of the first and second directions and may be absent from at least another side of the first light emitting area in another one of the first and second directions; and the one or more second structures may be present at sides of the second light emitting area in the one direction and the another direction.

In one or more example embodiments, the one or more first structures may be present at at least one side of the first light emitting area in one of the first and second directions, and one or more other structures may be present at at least another side of the first light emitting area in another one of the first and second directions; and the one or more second structures may be present at sides of the second light emitting area in the one direction and the another direction.

In one or more example embodiments, the one or more first structures may include at least one of a first layer and a second layer; the one or more second structures may include at least one of a third layer and a fourth layer; the first layer may be formed of a same layer as an insulating layer; the second layer may be formed of a same layer as a planarization layer; the third layer may be formed of a same layer as the insulating layer; the fourth layer may be formed of a same layer as the planarization layer; the second layer may be disposed above the first layer; and the fourth layer may be disposed above the third layer.

In one or more example embodiments, the first light emitting area may be larger than the second light emitting area; each of the first light emitting area and the second light emitting area may have a polygonal shape; the one direction may be same as the first direction; the another direction may be same as the second direction; and the second direction may be perpendicular to the first direction.

In one or more example embodiments, the range of the first viewing angle may be greater than the range of the second viewing angle; and the range of the one viewing angle may be same as the range of the another viewing angle.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure. The scope of protection of the present disclosure should be construed based on the following claims, and all technical features within the scope of equivalents thereof should be construed as being included within the scope of the present disclosure.

What is claimed is:

1. A display device, comprising:
a first light emitting area;
a second light emitting area;
a first depressed portion corresponding to the first light emitting area;
a second depressed portion corresponding to the second light emitting area;
a first lens corresponding to the first depressed portion; and
a second lens corresponding to the second depressed portion,
wherein:
an area of the first depressed portion is greater than an area of the second depressed portion; and
an area of the first lens is greater than an area of the second lens.

2. The display device of claim 1, wherein a total number of lenses included in the first lens is greater than a total number of lenses included in the second lens.

3. The display device of claim 1, wherein a shape of the first lens is different from a shape of the second lens.

4. The display device of claim 1, wherein:
in a wide viewing angle mode, the display device is configured to enable the first light emitting area to emit light and configured to prevent the second light emitting area from emitting light; and
in a narrow viewing angle mode, the display device is configured to enable the second light emitting area to emit light and configured to prevent the first light emitting area from emitting light; and
a viewing angle in the wide viewing angle mode is greater than a viewing angle in the narrow viewing angle mode.

5. The display device of claim 1, wherein:
the first lens overlaps with at least a portion of the first depressed portion; and
the second lens overlaps with at least a portion of the second depressed portion.

6. The display device of claim 1, wherein:
a largest thickness of one or more lenses included in the second lens is greater than a largest thickness of one or more lenses included in the first lens.

7. The display device of claim 1, wherein:
the first light emitting area is represented by a first open area;
the second light emitting area is represented by a second open area; and
the first open area is greater than the second open area.

8. The display device of claim 7, wherein:
an inclined portion of the first depressed portion surrounds at least a portion of the first open area along one direction; and
an inclined portion of the second depressed portion completely surrounds the second open area along at least two directions.

9. The display device of claim 7, wherein:
the first lens covers at least a portion of the first open area and covers at least a portion of the first depressed portion; and
the second lens covers at least a portion of the second open area and covers at least a portion of the second depressed portion.

10. The display device of claim 7, wherein:
a shape of the first lens corresponds to a shape of the first open area;
a shape of the second lens corresponds to a shape of the second open area; and
the shape of the second open area is different from the shape of the first open area.

11. The display device of claim 7, comprising a bank layer that overlaps at least a portion of the first depressed portion and at least a portion of the first lens,
wherein the first open area includes an opening in the bank layer, and the first open area overlaps with the first depressed portion.

12. The display device of claim 1, wherein:
the first depressed portion includes a first flat portion and a first inclined portion; and
the first inclined portion surrounds at least a portion of the first flat portion.

13. The display device of claim 12, wherein:
one or more insulating layers comprise the first flat portion and the first inclined portion.

14. The display device of claim 13, comprising a first light emitting element corresponding to the first light emitting area,
wherein the first light emitting element comprises a first electrode, an emission layer, and a second electrode.

15. The display device of claim 14, wherein:
the first electrode is disposed on the first flat portion, the first inclined portion, and a peripheral portion of the one or more insulating layers;
the peripheral portion of the one or more insulating layers surrounds the first depressed portion and is located around the first depressed portion; and
the emission layer is disposed on the first electrode and overlaps the first flat portion.

16. The display device of claim 15, comprising a bank layer that overlaps the first inclined portion and the peripheral portion of the one or more insulating layers,
wherein the second electrode is disposed on the emission layer and the bank layer.

17. The display device of claim 14, wherein:
the emission layer overlaps the first inclined portion;
the emission layer has a first thickness in an area overlapping the first flat portion;
the emission layer has a second thickness in an area overlapping the first inclined portion; and
the second thickness is less than the first thickness.

18. The display device of claim 12, wherein:
the first inclined portion surrounds the first flat portion along a first direction; and
the first inclined portion does not surround the first flat portion along a second direction.

19. The display device of claim 18, wherein:
the second depressed portion includes a second flat portion and a second inclined portion; and
the second inclined portion completely surrounds the second flat portion along two directions.

20. The display device of claim 1, comprising a first planarization layer that surrounds at least a portion of the first lens.

21. The display device of claim 20, wherein:
the first planarization layer surrounds at least side surfaces of the first lens along a first direction; and
the first planarization layer does not surround side surfaces of the first lens along a second direction.

22. The display device of claim 21, wherein the first planarization layer surrounds the second lens along the first direction and the second direction.

23. The display device of claim 20, comprising a second planarization layer that covers the first lens,
wherein a refractive index of the second planarization layer is less than a refractive index of the first lens.

24. The display device of claim 20, comprising:
a touch interlayer insulating layer disposed below the first planarization layer; and
a first color filter disposed between the first lens and the touch interlayer insulating layer.

25. The display device of claim 23, comprising a first color filter disposed between the second planarization layer and the first lens.

26. The display device of claim 25, comprising:
a touch sensor disposed on the first planarization layer; and
a second color filter disposed on the touch sensor and overlapping with at least a part of the first lens,
wherein the first color filter is disposed on the second color filter and covering the first lens.

27. The display device of claim 1, wherein the second lens is a color filter.

28. The display device of claim 1, wherein:
a subpixel having the first depressed portion and the first lens is associated with a first color; and
a subpixel having the second depressed portion and the second lens is associated with the same first color.

29. The display device of claim 1, comprising:
a touch sensor; and
a first color filter disposed on the touch sensor.

30. The display device of claim 29, wherein the first color filter is disposed on the first lens.

31. The display device of claim 29, comprising:
a second color filter,
wherein both the first color filter and the second color filter overlap the touch sensor.

32. A display device, comprising:
a first emission layer; and
a second emission layer,
wherein:
in a first mode, the display device is configured to emit light from the first emission layer and prevent emitting light from the second emission layer;
in a second mode, the display device is configured to emit light from the second emission layer and prevent emitting light from the first emission layer;
in the first mode, the light from the first emission layer provides a first viewing angle in a first direction and a second viewing angle in a second direction;
in the second mode, the light from the second emission layer provides one viewing angle in one direction and another viewing angle in another direction;
the second emission layer is different from the first emission layer;
the second mode is different from the first mode;
the second direction is different from the first direction;
the another direction is different from the one direction; and
a range of the first viewing angle is greater than a range of each of the second viewing angle, the one viewing angle, and the another viewing angle.

33. The display device of claim 32, comprising:
a first light emitting area; and
a second light emitting area,
wherein:
the first emission layer corresponds to the first light emitting area;
the second emission layer corresponds to the second light emitting area; and
the second light emitting area is separate and different from the first light emitting area.

34. The display device of claim 33, comprising:
one or more first structures corresponding to the first emission layer; and
one or more second structures corresponding to the second emission layer,
wherein:
the one or more first structures are disposed adjacent to at least a portion of the first emission layer in a plan view;
the one or more second structures are disposed adjacent to at least a portion of the second emission layer in a plan view;
in the first mode, the one or more first structures are configured to adjust the light from the first emission layer and to cause the range of the first viewing angle to be greater than the range of the second viewing angle; and
in the second mode, the one or more second structures are configured to adjust the light from the second emission layer and to cause the range of each of the one viewing angle and the another viewing angle to be less than the range of the first viewing angle.

35. The display device of claim 34,
the one or more first structures are present at at least one side of the first light emitting area in one of the first and second directions and are absent from at least another side of the first light emitting area in another one of the first and second directions; and
the one or more second structures are present at sides of the second light emitting area in the one direction and the another direction.

36. The display device of claim 34,
the one or more first structures are present at at least one side of the first light emitting area in one of the first and second directions, and one or more other structures are present at at least another side of the first light emitting area in another one of the first and second directions; and
the one or more second structures are present at sides of the second light emitting area in the one direction and the another direction.

37. The display device of claim 34, wherein:
the one or more first structures comprise at least one of a first layer and a second layer;
the one or more second structures comprise at least one of a third layer and a fourth layer;
the first layer is formed of a same layer as an insulating layer;
the second layer is formed of a same layer as a planarization layer;
the third layer is formed of a same layer as the insulating layer;
the fourth layer is formed of a same layer as the planarization layer;
the second layer is disposed above the first layer; and
the fourth layer is disposed above the third layer.

38. The display device of claim 33, wherein:
the first light emitting area is larger than the second light emitting area;
each of the first light emitting area and the second light emitting area has a polygonal shape;
the one direction is same as the first direction;
the another direction is same as the second direction; and
the second direction is perpendicular to the first direction.

39. The display device of claim 32, wherein:
the range of the first viewing angle is greater than the range of the second viewing angle; and
the range of the one viewing angle is same as the range of the another viewing angle.
